(19) United States
(12) Patent Application Publication
(10) Pub. No.: US 2024/0194636 A1
(43) Pub. Date: Jun. 13, 2024

(54) BONDING APPARATUS, BONDING METHOD, AND ARTICLE MANUFACTURING METHOD

(71) Applicant: CANON KABUSHIKI KAISHA, Tokyo (JP)

(72) Inventor: KENICHIRO MORI, Tochigi (JP)

(21) Appl. No.: 18/527,552

(22) Filed: Dec. 4, 2023

(30) Foreign Application Priority Data
Dec. 7, 2022 (JP) 2022-195859

(51) Int. Cl. H01L 23/00; H01L 21/67

(52) U.S. Cl. CPC H01L 24/80; H01L 21/67144; H01L 24/75; H01L 24/81; H01L 2224/75753; H01L 2224/80895; H01L 2224/80896; H01L 2224/81132; H01L 2224/81895

(57) ABSTRACT

The present invention provides a bonding apparatus for performing a bonding process of bonding, to one of a plurality of regions in a first object to be bonded, a second object to be bonded, comprising: a holder configured to hold the second object; a surface treatment device configured to perform a surface treatment which includes activating a surface state of a target bonding surface of the second object held by the holder; and a controller configured to, after the surface treatment is performed for the second object by the surface treatment device, control the bonding process such that the second object is bonded to one of the plurality of regions in a state in which the second object is held by the holder.

### BACKGROUND OF THE INVENTION

### Field of the Invention

The present invention relates to a bonding apparatus, a bonding method, and an article manufacturing method.

### Description of the Related Art

Japanese Patent Laid-Open No. 2013-243333 proposes a method of performing a surface activation process and a hydrophilic process for each of a substrate and a chip (die), and then temporarily bonding the substrate and the chip and performing heat treatment, thereby obtaining a predetermined conductivity or bonding strength between the substrate and the chip.

When bonding the substrate (first object to be bonded) and the chip (second object to be bonded), the longer the time from the surface treatment such as the surface activation process or the hydrophilic process for the chip to the bonding process between the chip and the substrate is, the lower the bonding strength tends to be. For this reason, the time from the surface treatment to the bonding process is demanded to be shortened as much as possible.

In the method described in Japanese Patent Laid-Open No. 2013-243333, a surface treatment apparatus that performs a surface activation process and a hydrophilic process, and a bonding apparatus that bonds a chip and a substrate are separately provided, and a conveyance unit conveys a plurality of chips from the surface treatment apparatus to the bonding apparatus. Hence, during the conveyance of the plurality of chips from the surface treatment apparatus to the bonding apparatus, the surface state of each chip may change, and the bonding strength may be insufficient.

### SUMMARY OF THE INVENTION

The present invention provides, for example, a technique advantageous in terms of the bonding strength between a first object to be bonded and a second object to be bonded.

According to one aspect of the present invention, there is provided a bonding apparatus for performing a bonding process of bonding, to one of a plurality of regions in a first object to be bonded, a second object to be bonded, comprising: a holder configured to hold the second object; a surface treatment device configured to perform a surface treatment which includes activating a surface state of a target bonding surface of the second object held by the holder; and a controller configured to, after the surface treatment is performed for the second object by the surface treatment device, control the bonding process such that the second object is bonded to one of the plurality of regions in a state in which the second object is held by the holder.

Further features of the present invention will become apparent from the following description of exemplary embodiments with reference to the attached drawings.

### BRIEF DESCRIPTION OF THE DRAWINGS

FIG. 1 is a schematic view showing a bonding apparatus according to the first embodiment;

FIG. 2 is a schematic view showing an example of the configuration of a wafer stage according to the first embodiment;

FIG. 3 is a flowchart showing the operation procedure of the bonding apparatus;

FIGS. 4A to 4C are views for explaining the operation of the bonding apparatus;

FIG. 5 is a flowchart showing an offset amount decision method;

FIG. 6 is a schematic view showing a bonding apparatus according to the second embodiment;

FIG. 7 is a schematic view showing an example of the configuration of a wafer stage according to the second embodiment;

FIG. 8 is a schematic view showing a bonding apparatus according to the third embodiment;

FIG. 9 is a schematic view showing an example of the configuration of a bonding stage according to the third embodiment;

FIG. 10 is a schematic view showing a bonding apparatus according to the fourth embodiment; and

FIG. 11 is a schematic view showing an example of the configuration of a bonding stage according to the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a first object to be bonded are defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

In embodiments to be described later, an example in which a wafer (substrate) on which semiconductor devices are formed is used as a first object to be bonded, and a die (chip) obtained by dividing into pieces a wafer on which semiconductor devices are formed is used as a second object to be bonded will be explained. However, the first object and the second object are not limited to these, and various changes and modifications can be made within the scope of the present invention. Examples of the first object are a silicon wafer, a silicon wafer on which wirings are formed, a glass wafer, a glass panel on which wirings are formed, an organic panel (PCB) on which wirings are formed, and a metal panel, in addition to a wafer on which semiconductor devices are formed. The first object may be a wafer to which one or more dies are already bonded. Also, examples of the second object are a stack of dies, a small piece of a material, an optical element, a MEMS, and a structure, in addition to a die obtained by dividing into pieces a wafer on which semiconductor devices are formed.

In the embodiments to be described later, various temporary or permanent bonding methods can be applied as a bonding method for the first object and the second object. Examples of the bonding method are bonding using an adhesive, temporary bonding using a temporary adhesive, bonding by hybrid bonding, atomic diffusion bonding, vacuum bonding, and bump bonding.

Industrial application examples of the embodiments to be described later will be explained next.

The first application example is manufacturing of a stacked memory. In a case where a bonding apparatus according to the embodiments to be described later is applied to manufacturing of a stacked memory, a wafer (substrate) on which a memory serving as a semiconductor device is formed is used as the first object, and a die (chip) on which a memory is formed is used as the second object. For example, in manufacturing of a stacked memory having eight memory layers, the second object (die) formed as the eighth memory layer is bonded on the first object (substrate) already having seven memory layers. Note that the final layer of the stacked memory may be not a memory layer but a layer on which a driver for driving the memory is formed.

The second application example is heterogeneous integration of a processor. The mainstream of conventional processors is a System On Chip (SoC) in which a logic circuit, a Static Random Access Memory (SRAM), and the like are formed in one semiconductor element. To the contrary, in heterogeneous integration, a plurality of types of elements are formed from separate wafers by applying a process optimal for each element, and bonded to manufacture a processor. This can implement cost reduction and yield improvement of processors. In a case where the bonding apparatus according to the embodiment to be described later is applied to heterogeneous integration, a wafer (substrate) on which a logic device serving as a semiconductor device is formed is used as the first object. A die (chip) separated after probing, such as an SRAM, an antenna, or a driver, is used as the second object. In heterogeneous integration, for example, dies of different types are sequentially bonded, so bonded objects to the first object sequentially increase. More specifically, when a die having an SRAM is bonded onto a logic wafer, the logic wafer is the first object and the die having the SRAM is the second object. When a die having an element to be formed on the SRAM is bonded onto the die having the SRAM, a die having a logic wafer and an SRAM is the first object, and the die having the element is the second object. Note that when bonding a plurality of dies to overlap each other, as for the order of bonding, bonding is preferably started from a thin die such that a bonding head does not interfere with a bonded die.

The third application example is 2.5D bonding using a silicon interposer. The silicon interposer is a silicon wafer on which wirings are formed. The 2.5D bonding is a method of bonding a plurality of types of dies onto the silicon interposer, and electrically connecting the plurality of types of dies by the wirings on the silicon interposer. In a case where the bonding apparatus according to the embodiment to be described later is applied to the 2.5D bonding, a silicon wafer on which wirings are formed is used as the first object, and a separated die is used as the second object. In the 2.5D bonding, for example, a plurality of types of dies are bonded to the silicon interposer, so the structure of a silicon interposer to which one or more dies are already bonded is sometimes handled as the first object. Note that when bonding a plurality of dies to the silicon interposer, as for the order of bonding, bonding is preferably started from a thin die such that a bonding head does not interfere with a bonded die.

The fourth application example is 2.1D bonding using an organic interposer or a glass interposer. The organic interposer is an organic panel (a PCB substrate or a CCL substrate) used as a package substrate, on which wirings are formed. The glass interposer is a glass panel on which wirings are formed. The 2.1D bonding is a method of bonding a plurality of types of dies to the organic interposer or the glass interposer, and electrically bonding the plurality of types of dies by the wirings on the interposer. In a case where the bonding apparatus according to the embodiment to be described later is applied to the 2.1D bonding, in 2.1D bonding using the organic interposer, an organic panel on which wirings are formed is used as the first object, and a separated die is used as the second object. To the contrary, in 2.1D bonding using the glass interposer, a glass panel on which wirings are formed is used as the first object, and a separated die is used as the second object. In the 2.1D bonding, for example, a plurality of types of dies are bonded to the organic interposer or the glass interposer, so the structure of an organic interposer or a glass interposer to which one or more dies are already bonded is sometimes handled as the first object. Note that when bonding a plurality of dies to the interposer, as for the order of bonding, bonding is preferably started from a thin die such that a bonding head does not interfere with a bonded die.

The fifth application example is temporary bonding in a fan-out package manufacturing process. For example, fan-out packaging as advanced packaging applied to a semiconductor manufacturing process includes fan-out wafer-level packaging and fan-out panel-level packaging. The fan-out wafer-level packaging is a process of reconstructing separated dies into a wafer shape using a mold resin to do packaging. The fan-out panel-level packaging is a process of reconstructing separated dies into a panel shape using a mold resin to do packaging. In such fan-out packaging, rewirings from the dies to bumps are formed, or rewirings that bond different types of dies are formed on a molded reconstructed substrate. At this time, if the die array accuracy is low, when transferring the rewiring pattern using a step-and-repeat exposure apparatus, it may be difficult to accurately align the rewiring pattern to the dies. For this reason, the plurality of dies are required to be arrayed accurately in the fan-out packaging. In a case where the bonding apparatus according to the embodiment to be described later is applied to the fan-out package manufacturing process, a metal panel is used as the first object and a separated die is used as the second object. More specifically, the separated dies are temporarily bonded in series to the metal panel by a temporary adhesive using the bonding apparatus. After that, the plurality of dies temporarily bonded on the metal panel are molded into a wafer shape or a panel shape by a molding apparatus, and peeled from the metal panel after molding. Accordingly, a reconstructed wafer or a reconstructed panel on which the plurality of dies are arrayed is manufactured. Note that in the fan-out package manufacturing process, the array of the plurality of dies may change in the molding process. Thus, in temporarily bonding the plurality of dies onto the metal panel using the bonding apparatus, the bonding position of each die on the metal panel is preferably adjusted to correct the change of the array caused by the molding process.

The sixth application example is heterogeneous substrate bonding. For example, in an infrared image sensor, InGaAs known as a high-sensitivity material is used for a sensor unit configured to receive light, and silicon capable of implementing high-speed processing is used for a logic circuit configured to extract data. Accordingly, a high-sensitivity high-speed infrared image sensor can be manufactured. However, from InGaAs crystal, only wafers whose diameter is as small as 4 inches are mass-produced, which is smaller than a mainstream 300-mm silicon wafer. Hence, there has been proposed a method of bonding, to a 300-mm silicon wafer on which a logic circuit is formed, a die obtained by dividing an InGaAs substrate into pieces. The bonding apparatus according to the embodiment to be described later can also be applied to heterogeneous substrate bonding of bonding substrates made of different materials and having different sizes. In the application of the bonding apparatus to heterogeneous substrate bonding, a substrate with a large diameter such as a silicon wafer is used as the first object, and a die (small piece) of a material such as InGaAs is used as the second object. Note that the die (small piece) of the material such as InGaAs may be a slice of a crystal and is preferably cut into a rectangular shape.

### First Embodiment

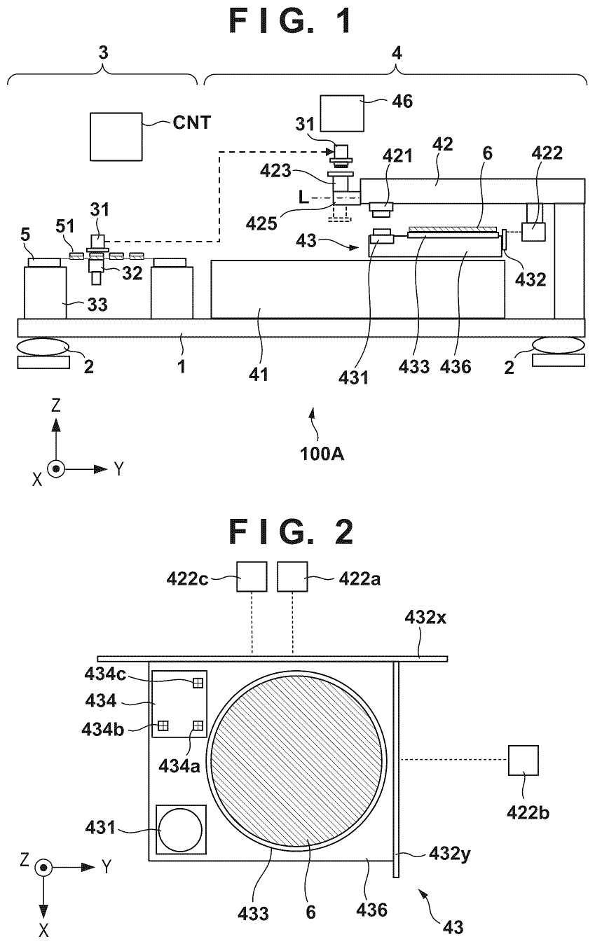

The first embodiment according to the present invention will be described. FIG. 1 is a schematic view showing a bonding apparatus 100A according to the first embodiment. In FIG. 1, a direction vertical to the upper surface (target bonding surface) of a wafer 6 held by a wafer stage 43 is defined as the Z direction, and directions orthogonal to each other in a plane parallel to the upper surface of the wafer 6 are defined as the X direction and the Y direction. The bonding apparatus 100A is an apparatus that sequentially bonds a die 51 that is a second object to each of a plurality of regions on the wafer 6 (substrate) that is a first object. The plurality of dies 51 are supported by a dicing frame 5 serving as a support member. More specifically, the plurality of dies 51 are arranged on a dicing tape adhered to the dicing frame 5.

As shown in FIG. 1, the bonding apparatus 100A according to this embodiment includes a pickup unit 3, a bonding unit 4, and a controller CNT. The pickup unit 3 and the bonding unit 4 are mounted on a base 1 damped by mounts 2. The pickup unit 3 and the bonding unit 4 are mounted on the same base 1 in this embodiment, but may be individually mounted on separate bases.

The pickup unit 3 includes a pickup head 31, a release head 32, and a frame holder 33. The pickup unit 3 picks up the dies 51 one by one from the dicing tape adhered to the dicing frame 5. The frame holder 33 holds the dicing frame 5. The release head 32 pushes up the target die 51 from the back side of the dicing tape adhered to the dicing frame 5 such that the target die 51 to be picked up projects upward from the remaining dies. At this time, the target die 51 is partially peeled from the dicing tape. The pickup head 31 holds (sucks) by a vacuum suction force or the like the target die 51 pushed up by the release head 32, and peels (separates) the target die 51 from the dicing tape. The pickup head 31 moves from the pickup unit 3 to the bonding unit 4 and transfers the die 51 to a bonding head 423 to be described later. In this embodiment, a target bonding surface (surface to be bonded) of the die 51 transferred to the bonding head 423 faces up.

Here, the pickup head 31 contacts the target bonding surface of the die 51. It is therefore preferable that the pickup head 31 generates no static electricity and prevents a foreign object from sticking. More specifically, the pickup head 31 is discharged by an ionizer, and/or a pin pattern or a ring pattern is formed on the holding surface of the pickup head 31 for the die 51 to reduce the contact area. A noncontact chuck such as a Bernoulli chuck or a chuck that holds an edge surface of a die or a side surface of a die may be used.

The bonding unit 4 includes a stage base 41 and an upper base 42, and the wafer stage 43 is mounted on the stage base 41. The wafer stage 43 (first holder) is configured to hold the wafer 6 and move on the stage base 41. More specifically, the wafer stage 43 includes a wafer chuck 433 that holds the wafer 6 (substrate) by a vacuum suction force or the like, and a driving mechanism 436 that drives the wafer chuck 433 (wafer 6). The driving mechanism 436 includes an actuator such as a linear motor, and is configured to drive the wafer 6 in the X and Y directions and the θZ direction (the rotational direction about the Z-axis). The driving mechanism 436 may be configured to drive the wafer 6 in the Z direction. A relative rotational operation of the wafer 6 and the die 51 in the θZ direction can be performed by rotating the wafer 6 by the wafer stage 43 (driving mechanism 436) and/or rotating the die 51 by the bonding head 423.

The wafer stage 43 also includes a mirror 432 for measuring the position of the wafer stage 43 in the X and Y directions. The mirror 432 serves as the target of an interferometer 422 that measures the position of the wafer stage 43 in the X and Y directions. The interferometer 422 is mounted on the upper base 42, irradiates the mirror 432 provided on the wafer stage 43 with light, and measures the position of the wafer stage 43 based on reflected light from the mirror 432. The controller CNT can control the position of the wafer stage 43 (wafer 6) in the X and Y directions and the θZ direction based on the position of the wafer stage 43 measured by the interferometer 422.

Also, a die observation camera 431 (die image capturing device) is mounted on the wafer stage 43. The die observation camera 431 is a camera for observing the target bonding surface of the die 51. The die observation camera 431 can be arranged so that it can capture an image of the target bonding surface of the die 51 in a state in which the die 51 is held by the bonding head 423 (holder), and the target bonding surface of the die 51 faces down. In this embodiment, the die observation camera 431 is mounted on the wafer stage 43 (driving mechanism 436) and can move in the X and Y directions along with movement of the wafer stage 43. The die observation camera 431 is used to obtain (measure) information representing the position of a pattern provided on the target bonding surface of the die 51. For example, using a known image processing technique, the controller CNT detects the position of a feature point on the target bonding surface of the die 51 from an image obtained by capturing the target bonding surface of the die 51 by the die observation camera 431. Thus, the controller CNT can measure the position of the pattern of the die 51 held by the bonding head 423 in the X and Y directions and/or the θZ direction.

Mechanisms mounted on the upper base 42 will be described next. The bonding head 423, a driving unit 425 (driver), and a wafer observation camera 421 are mounted on the upper base 42.

The bonding head 423 (second holder) holds by a vacuum suction force or the like the die 51 transferred from the pickup head 31, and drives the die 51 in the −Z direction to bond the die 51 to the wafer 6. The bonding head 423 is driven by the driving unit 425. The driving unit 425 drives the bonding head 423, thereby moving the die 51 between a surface treatment position at which surface treatment of the target bonding surface of the die 51 is performed by a surface treatment unit 46 (surface treatment device) to be described later and a bonding process position at which the bonding process of bonding the die 51 to the wafer 6 is performed. That is, the driving unit 425 switches the position of the die 51 between the surface treatment position and the bonding process position. In this embodiment, the direction of the target bonding surface of the die 51 changes between the surface treatment position (first position) and the bonding process position (second position). In the example shown in FIG. 1, the target bonding surface of the die 51 arranged at the surface treatment position faces up, and the target bonding surface of the die 51 arranged at the bonding process position faces down. The direction of the target bonding surface of the die 51 is reversed between the surface treatment position and the bonding process position. For this reason, the driving unit 425 is configured to rotationally drive the bonding head 423 with respect to an axis L parallel to the Y direction as the center. Thus, the die 51 can be moved between the surface treatment position and the bonding process position such that the direction of the target bonding surface of the die 51 changes between the surface treatment position and the bonding process position (in the example shown in FIG. 1, the direction of the target bonding surface of the die 51 is reversed).

Here, in this embodiment, since the surface treatment is performed in a state in which the die 51 is held by the bonding head 423, the holding surface of the bonding head 423 for the die 51 is preferably made of a material hard to be damaged by the surface treatment. Also, a fixing mechanism for fixing (locking) the position of the bonding head 423 is preferably provided on the driving unit 425 such that neither vibration nor drift in the rotational direction occurs in the bonding head 423 in the bonding process. Bonding of the die 51 to the wafer 6 can be done by relatively driving the die 51 and the wafer 6 by the bonding head 423 and the wafer stage 43. Bonding of the die 51 to the wafer 6 may be performed by driving the die 51 in the −Z direction by the bonding head 423 or by driving the wafer 6 in the +Z direction by the wafer stage 43.

The wafer observation camera 421 (wafer image capturing device) is a camera for observing the target bonding surface of the wafer 6. The wafer observation camera 421 can be arranged so that it can capture an image of the wafer 6 in a state in which the wafer 6 is held by the wafer stage 43. The wafer observation camera 421 is used to obtain (measure) information representing the position of a pattern provided on the target bonding surface of the wafer 6. For example, using a known image processing technique, the controller CNT detects the position of a feature point on the target bonding surface of the wafer 6 from an image obtained by capturing the target bonding surface of the wafer 6 by the wafer observation camera 421. Thus, the controller CNT can measure the position of the pattern of the wafer 6 held by the wafer stage 43 in the X and Y directions and/or the θZ direction.

Here, the relative position between the wafer observation camera 421 and the die observation camera 431 is preferably calibrated to accurately reduce a bonding deviation between the wafer 6 and the die 51 in the bonding process. Hence, for the calibration, marks observable by one or both of the wafer observation camera 421 and the die observation camera 431 are preferably arranged (mounted) on the bonding apparatus 100A.

The bonding apparatus 100A according to this embodiment is provided with the surface treatment unit 46. The surface treatment unit 46 performs surface treatment for the held surface of the die 51 in a state in which the die 51 is held by the bonding head 423 such that the die 51 is arranged at the surface treatment position (that is, such that the target bonding surface of the die 51 faces up). The surface treatment includes an activation treatment of activating the surface state of the held surface of the die 51. In this case, the surface treatment unit 46 includes, for example, an atmospheric pressure plasma activation device, which generates a plasma under the atmospheric pressure to give a predetermined energy to particles, and making the particles hit the held surface of the die 51, thereby activating the held surface of the die 51. Also, the surface treatment may include a washing treatment of washing the held surface of the die 51 and/or lyophilic treatment of making the held surface of the die 51 lyophilic (hydrophilic). In this case, the surface treatment unit 46 can include, for example, a washing device that supplies a predetermined liquid to the held surface of the die 51 and thus washes the held surface of the die 51 and/or a lyophilic device that supplies a predetermined liquid to the held surface of the die 51 and thus makes the held surface of the die 51 lyophilic. Note that as the predetermined liquid used by the washing device or the lyophilic device, water or a liquid containing an OH group can be used. However, the liquid is not limited to these.

The controller CNT is formed from, for example, a computer (information processing apparatus) including a processor such as a Central Processing Unit (CPU) and a storage such as a memory. The controller CNT controls the surface treatment and the bonding process by controlling each unit of the bonding apparatus 100A. The surface treatment includes the activation treatment, as described above, and may additionally include the washing treatment and/or the lyophilic treatment. The bonding process is a process of aligning the wafer 6 and the die 51 such that the pattern of the wafer 6 and the pattern of the die 51 overlap each other and bonding the die 51 on the wafer 6. More specifically, the controller CNT obtains the position of the pattern provided on the target bonding surface of the wafer 6 based on an image of the target bonding surface of the wafer 6 that is captured by the wafer observation camera 421. Also, the controller CNT obtains the position of the pattern provided on the target bonding surface of the die 51 based on an image of the target bonding surface of the die 51 that is captured by the die observation camera 431. The controller CNT can control the bonding process based on the position of the pattern of the wafer 6 and that of the pattern of the die 51.

There is recently proposed a technique called Chiplet which implements a high-performance semiconductor element in one package by bonding different dies by high-density I/O. In the Chiplet technique, the interval of high-density I/Os arranged on each die is about 1 μm, and a bonding position accuracy of about 100 nm is necessary. Since the bonding position accuracy of a bonding apparatus in practical use is about 2 μm, the bonding apparatus 100A is required to accurately perform alignment between the wafer 6 and the die 51 and further improve the bonding position accuracy.

A detailed example of the configuration of the wafer stage 43 will be described next. FIG. 2 is a view showing the wafer stage 43 viewed from the +Z direction. The wafer 6 is held by the wafer chuck 433. To perform two-dimensional positioning, the wafer stage 43 includes a bar mirror 432x for performing position measurement in the X direction and the θZ direction (rotational direction), and a bar mirror 432y for performing position measurement in the Y direction. The bar mirror 432x is the target of interferometers 422a and 422c that perform position measurement in the X direction. The interferometers 422a and 422c are arranged apart in the Y direction. The rotational amount (θZ direction) of the wafer stage 43 can be obtained from the difference between the measurement result of the interferometer 422a and that of the interferometer 422c. The bar mirror 432y is the target of an interferometer 422b that performs position measurement in the Y direction. The interferometers 422a to 422c measure in real time the position of the wafer stage 43 in the X direction, the position in the Y direction, and the rotational amount in the θZ direction. The controller CNT can perform feedback control of driving of the wafer stage 43 in real time and two-dimensionally position the wafer stage 43 accurately. In the bonding apparatus 100A according to this embodiment, accurate position measurement by the interferometers 422a to 422c, and feedback control of the driving mechanism of the wafer stage 43 based on the result of the position measurement can function as the positioning mechanism of the wafer stage 43.

A reference plate 434 including a plurality of marks 434a to 434c is mounted on the wafer stage 43. The reference plate 434 is made of a material with a low thermal expansion coefficient, and includes the marks 434a to 434c formed (drawn) at a high position accuracy. For example, the reference plate 434 can be formed by drawing marks on a quartz substrate using the drawing method of a semiconductor lithography process. The reference plate 434 can be arranged to have a surface substantially flush with the surface of the wafer 6. In this embodiment, the reference plate 434 can be observed by the wafer observation camera 421, but the present invention is not limited to this when a reference plate observation camera is separately provided. The wafer stage 43 may be constituted by a coarse motion stage that can be driven within a large range, and a fine motion stage that can accurately be driven within a small range on the coarse motion stage. In this case, the die observation camera 431, the mirror 432, the wafer chuck 433, and the reference plate 434 require accurate positioning and thus are preferably fixed to the fine motion stage.

A method of guaranteeing the origin position, magnification, the X-axis and Y-axis directions (rotation), and the orthogonality of the wafer stage 43 using the reference plate 434 will be described. While controlling the wafer observation camera 421 to capture (observe) an image of the mark 434a, the controller CNT obtains the measured values of the interferometers 422a to 422c when the mark 434a is arranged at the center of the image obtained by the wafer observation camera 421. The obtained measured values are set as the origin of the wafer stage 43. Then, while controlling the wafer observation camera 421 to capture (observe) an image of the mark 434b, the controller CNT obtains the measured values of the interferometers 422a to 422c when the mark 434b is arranged at the center of the image obtained by the wafer observation camera 421. From the obtained measured values, the controller CNT decides the Y-axis direction and Y magnification of the wafer stage 43. Next, while controlling the wafer observation camera 421 to capture (observe) an image of the mark 434c, the controller CNT obtains the measured values of the interferometers 422a to 422c when the mark 434c is arranged at the center of the image obtained by the wafer observation camera 421. From the obtained measured values, the controller CNT decides the X-axis direction and × magnification of the wafer stage 43. That is, a direction from the mark 434b toward the mark 434a on the reference plate 434 is defined as the Y-axis of the bonding apparatus 100A, a direction from the mark 434c toward the mark 434a is defined as the X-axis of the bonding apparatus 100A, and the directions and orthogonality of the axes are calibrated. Also, the interval between the mark 434b and the mark 434a is defined as the scale reference of the bonding apparatus 100A in the Y direction, the interval between the mark 434c and the mark 434a is defined as the scale reference of the bonding apparatus 100A in the X direction, and calibration is performed. The refractive index of the optical path of the interferometer changes due to variations of the atmospheric pressure and temperature, this makes the measured value vary, and thus it is preferable for the interferometers 422a to 422c to perform calibration at an arbitrary timing and guarantee the origin position, magnification, rotation, and orthogonality of the wafer stage 43. Note that to reduce variations of the measured values of the interferometers 422a to 422c, the space in which the wafer stage 43 moves may be covered with a temperature control chamber to control the temperature.

In this embodiment, an example in which the reference plate 434 is arranged on the wafer stage 43 and an image of the reference plate 434 is captured (observed) by the wafer observation camera 421 has been described, but the present invention is not limited to this. For example, the reference plate 434 may be arranged on the upper base 42 to capture (observe) an image of the reference plate 434 by the die observation camera 431. Even in this configuration, the origin position, magnification, rotation, and orthogonality of the wafer stage 43 can be guaranteed. In this embodiment, an example in which calibration is performed by capturing (observing) an image of the reference plate 434 has been described, but the present invention is not limited to this. For example, calibration may be performed by an abutting operation to a reference surface. Alternatively, accurate positioning of the wafer stage 43 may be performed using a position measurement means such as a white interferometer for which an absolute value is guaranteed.

To improve the bonding strength between the wafer 6 and the die 51, the time from the surface treatment of the target bonding surface of the die 51 to (the start of) the bonding process is preferably shortened as much as possible. Also, it is preferable to avoid another member from contacting the target bonding surface of the die 51 between the surface treatment and the bonding process. Hence, the bonding apparatus 100A according to this embodiment is provided with the surface treatment unit 46 that performs surface treatment for the target bonding surface of the die 51 in a state in which the die 51 is held by the bonding head 423, as described above. After the surface treatment is performed by the surface treatment unit 46, the bonding process of aligning the wafer 6 and the die 51 and bonding the die 51 to the wafer 6 is performed without canceling holding of the die 51 by the bonding head 423. This makes it possible to avoid another member from contacting the target bonding surface of the die 51 between the surface treatment and the bonding process, shorten the time from the surface treatment to the bonding process, and improve the bonding strength between the wafer 6 and the die 51.

### [Operation of Bonding Apparatus]

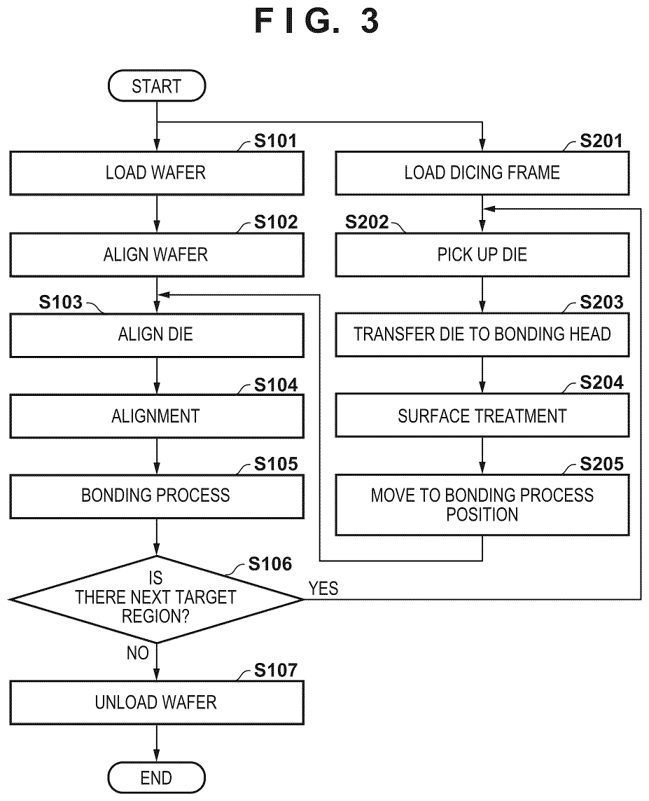

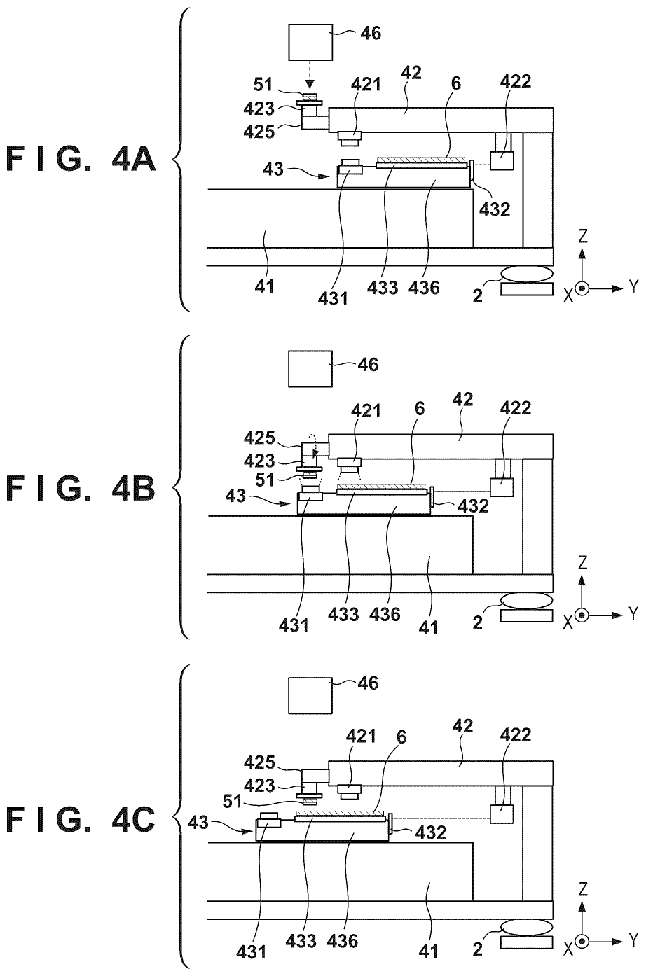

The operation (bonding method) of the bonding apparatus 100A according to this embodiment will be described below. FIG. 3 is a flowchart showing the operation procedure of the bonding apparatus 100A according to this embodiment. The controller CNT can execute processes in the flowchart of FIG. 3. FIGS. 4A to 4C are views for explaining the operation of the bonding apparatus 100A, and show only the bonding unit 4.

In step S101, the controller CNT loads the wafer 6 serving as a first object onto the wafer stage 43 (wafer chuck 433) of the bonding apparatus 100A using a wafer conveyance mechanism (not shown). At this time, the space in the bonding apparatus 100A is desirably kept at a high cleanliness of about class 1 because adhesion of a foreign substance to the target bonding surface of the wafer 6 causes a bonding failure. To maintain a high level of cleanliness even for the wafer 6, the wafer 6 is desirably stored in a container that has a high airtightness and maintains a high cleanliness, and loaded from the container onto the wafer stage 43 of the bonding apparatus 100A. The container is, for example, a Front Opening Unify Pod (FOUP).

To increase the cleanliness of the wafer 6, a washing mechanism that washes the wafer 6 may be provided in the bonding apparatus 100A. A mechanism that performs a preprocess for the bonding process on the wafer 6 may also be provided in the bonding apparatus 100A. For example, the preprocess is a process of applying an adhesive to the target bonding surface of the wafer 6 in bonding using an adhesive, or a process of activating the target bonding surface of the wafer 6 in hybrid bonding. After positions of the wafer 6 in the θZ direction and the X and Y directions are measured by a prealignment unit (not shown), the wafer 6 is coarsely positioned based on the measurement result and conveyed onto the wafer chuck 433 of the wafer stage 43. The position of the wafer 6 in the rotational direction can be measured by detecting a notch or orientation flat of the wafer 6, and the position of the wafer 6 in the X and Y directions can be measured by detecting the outer shape of the wafer 6.

In step S102, the controller CNT performs wafer alignment using the wafer observation camera 421. In the wafer alignment, the wafer observation camera 421 captures an image of the target bonding surface of a target region (bonding target) to which the die 51 is to be bonded in a plurality of regions of the wafer 6. Based on the obtained image, the position of a pattern provided on the target region is obtained. Note that each of the plurality of regions of the wafer 6 is a bonding region to which one die 51 should be bonded and will sometimes simply be referred to as “region” hereinafter.

Focus adjustment when capturing an image of the target bonding surface of the wafer 6 may be performed by a focus adjustment mechanism provided in the wafer observation camera 421, or by driving the wafer 6 in the Z direction by the Z driving mechanism of the wafer stage 43. When an alignment mark is provided on the target bonding surface of the wafer 6, the position of the pattern of the wafer 6 can be obtained using the alignment mark. To the contrary, when no alignment mark is provided on the target bonding surface of the wafer 6, the position of the pattern of the wafer 6 may be obtained using a feature point capable of specifying the position of the pattern of the wafer 6. As the feature point, for example, part of the pattern of the wafer 6 can be used.

For example, the controller CNT can measure the position of the pattern of the wafer 6 by measuring the image position of a projected alignment mark or feature point with respect to the center of the image obtained by the wafer observation camera 421. The alignment mark or feature point will be sometimes referred to as an alignment mark or the like. For example, there is a method of accurately measuring the position of the alignment mark or the like with respect to the reference point of the bonding apparatus 100A. According to this method, the wafer stage 43 is driven in advance to make a mark formed on the reference plate 434 fall within the visual field of image capturing of the wafer observation camera 421, and the wafer observation camera 421 captures an image of the mark on the reference plate 434. Based on the position of the wafer stage 43 at that time and the mark position within the image obtained by the wafer observation camera 421, the reference point of the bonding apparatus 100A is decided. Based on the image obtained by capturing the alignment mark or the like by the wafer observation camera 421, the offset amount of the position of the alignment mark or the like with respect to the reference point is obtained. Hence, the position of the alignment mark can be measured accurately from the position of the reference point and the offset amount. As the position of the reference point of the bonding apparatus 100A, the position of the specific mark on the reference plate 434 is used in this embodiment. However, the position of another place may be used if it is a position serving as a reference.

Since an interferometer 422 has a narrow measurement range in the rotational direction, a rotation amount that can be corrected by the wafer stage 43 is relatively small. If the rotation amount of the wafer 6 is large, the wafer 6 is preferably rearranged on the wafer stage 43 so as to correct the rotation amount of the wafer 6. When the wafer 6 is rearranged on the wafer stage 43, the position of the wafer 6 needs to be measured again. During execution of step S102, the surface position of the wafer 6 is preferably measured using a height measurement means (not shown) that measures the surface position (height) of the target bonding surface of the wafer 6. This is because the thickness of the wafer 6 varies, and the surface position of the wafer 6 is important to accurately manage (control) the gap between the wafer 6 and the die 51 in the bonding process.

The origin position, the magnification, the X-axis and Y-axis directions (rotation), and the orthogonality are guaranteed for the wafer stage 43 using the reference plate 434. For this reason, the position of the wafer 6 mounted on the wafer stage 43 with respect to the origin position of the wafer stage 43 and the like can be measured. On the wafer 6, regions (bonding targets or target regions) where semiconductor devices (patterns) are formed are repetitively arranged at a predetermined period. That is, the wafer 6 includes a plurality of regions to which the dies 51 are bonded, respectively. A semiconductor device in each region of the wafer 6 is accurately positioned and manufactured using a semiconductor manufacturing apparatus. A plurality of regions on the wafer 6 are accurately arrayed generally at a repetitive period with a nano-level accuracy. For this reason, in the wafer alignment of step S102, it is not necessary to measure the positions of all regions on the wafer 6, and it is only necessary to measure the positions of some of the plurality of regions on the wafer 6. More specifically, the positions of semiconductor devices (patterns or marks) in three or more regions out of a plurality of regions on the wafer 6 are measured, and statistical processing is performed. Accordingly, the array of regions on the wafer 6, the origin position of the array, the position in the X and Y directions, the rotation amount in the θZ direction, the orthogonality, and the magnification error of the repetitive period can be calculated.

The wafer chuck 433 may include a mechanism that controls the temperature of the wafer 6. This is because in a case where the thermal expansion coefficient of a silicon wafer is 3 ppm/° C., and the diameter of the wafer is 300 mm, if the temperature increases by 1ºC, the position of the outermost periphery moves by 150 mm×0.000003=0.00045 mm=450 nm. If a bonding position (for example, the position of the target region) moves after wafer alignment, it may be difficult to accurately bond the wafer 6 and the die 51. Thus, the temperature of the wafer 6 is preferably controlled to keep the temperature change of the wafer 6 to be 0.1° C. or less.

Note that in this embodiment, the wafer 6 is used as the first object. If an interposer on which wirings are formed is used as the first object, not the array of semiconductor devices but the array of the repetitively formed wirings is measured. If a wafer or panel without a pattern is used as the first object, wafer alignment in step S102 need not be executed.

Steps S101 and S102 described above are processes regarding the wafer 6 serving as the first object. In parallel to steps S101 and S102, processes (steps S201 to S205) regarding the die 51 serving as the second object are executed.

In step S201, the controller CNT loads the dicing frame 5 to the pickup unit 3 (onto the frame holder 33) using a conveyance mechanism (not shown). The dicing frame 5 is a frame having an opening at the center, and a dicing tape is adhered to the dicing frame 5 so as to cover the opening. A plurality of dies 51 divided by a cutter such as a dicer are arrayed on the dicing tape. Conventionally, the dicing frame 5 is conveyed by an unsealed magazine. However, adhesion of a foreign substance to the target bonding surface of the die 51 causes a bonding failure, so the dicing frame 5 needs to be conveyed in a container that has a high airtightness and maintains a high cleanliness. To increase the cleanliness of the die 51, a washing mechanism that washes the die 51 on the dicing frame 5 (dicing tape) may be provided inside the bonding apparatus 100A. After the rotational direction and the shift position (position in the X and Y directions) of the dicing frame 5 are coarsely determined by a prealignment unit (not shown) based on the outer shape of the dicing frame 5, the dicing frame 5 can be conveyed onto the frame holder 33.

In step S202, the controller CNT controls the pickup head 31 and the release head 32 to pick up one die 51 from the dicing frame 5 (dicing tape). More specifically, the controller CNT moves the pickup head 31 and the release head 32 to the position of the die 51 to be picked up (to be also referred to as the target die 51 hereinafter). The controller CNT drives the release head 32 in the +Z direction to push up the target die 51 from the back side of the dicing tape. In this state, the controller CNT drives the pickup head 31 in the −Z direction so that the pickup head 31 and the target die 51 come into contact with each other. The target die 51 is then held (sucked) by the pickup head 31 by a vacuum suction force or the like, and can be peeled from the dicing tape by driving the pickup head 31 in the +Z direction. The target die 51 to be picked up can be decided based on non-defective die (Known Good Die: KGD) information transmitted to the bonding apparatus 100A online. Normally, only non-defective dies are picked up as the target dies 51. However, as for a region having a defective device in the plurality of regions on the wafer 6, a defective die (Known Bad Die: KBD) may be picked up as the target die 51.

In step S203, the controller CNT transfers (delivers) the target die 51 picked up by the pickup head 31 to the bonding head 423 of the bonding unit 4. More specifically, the controller CNT arranges the pickup head 31 above the bonding head 423 by driving in the X direction the pickup head 31 picking up the target die 51. At this time, the bonding head 423 is driven (positioned) by the driving unit 425 such that the holding surface for holding the target die 51 faces up. The controller CNT then transfers the target die 51 from the pickup head 31 to the bonding head 423 by driving the pickup head 31 in the −Z direction. When picking up the target die 51 by the pickup head 31, the target bonding surface of the target die 51 faces up (is oriented in the +Z direction), and the target bonding surface of the target die 51 is held (contacted) by the pickup head 31. On the other hand, if the target die 51 is transferred from the pickup head 31 to the bonding head 423, the surface of the target die 51 on the opposite side of the target bonding surface is held by the bonding head 423.

In this embodiment, an example in which the pickup head 31 directly conveys the target die 51 to the bonding head 423 has been described, but the present invention is not limited to this. For example, when one or more conveyance mechanisms are provided on the conveyance path of the target die 51 to the bonding head 423, the target die 51 may be conveyed to the bonding head 423 through a process of transferring the target die 51 to the one or more conveyance mechanisms. Also, if one or more die holders are provided in the conveyance path of the target die 51 to the bonding head 423, the pickup head 31 may convey the target die 51 to the bonding head 423 after the target die 51 is re-held using the one or more die holders.

In step S204, the controller CNT causes the surface treatment unit 46 to execute surface treatment for improving the bonding strength between the wafer 6 and the target die 51 for the target bonding surface of the target die 51 held by the bonding head 423 (see FIG. 4A). At this time, the bonding head 423 is driven (positioned) by the driving unit 425 such that the target die 51 is arranged at a surface treatment position to perform the surface treatment by the surface treatment unit 46. In this embodiment, the surface treatment for the held surface of the target die 51 can be performed in a state in which the target bonding surface of the target die 51 faces up. As described above, the surface treatment includes an activation treatment of activating the surface state of the held surface of the target die 51. Also, the surface treatment may include a washing treatment of washing the held surface of the target die 51 and/or lyophilic treatment of making the held surface of the target die 51 lyophilic (hydrophilic). Here, in step S204, when applying bonding using an adhesive, a process of applying an adhesive to the target bonding surface of the target die 51 may be executed. When applying bump bonding, a heating process for melting bumps of the target die 51 or a flux application process may be executed.

In step S205, the controller CNT causes the driving unit 425 to rotationally drive the bonding head 423 such that the target die 51 held by the bonding head 423 is arranged at the bonding process position (see FIG. 4B). The target bonding surface of the target die 51 held by the bonding head 423 thus faces down, and the target bonding surface of the target die 51 and the target bonding surface of the wafer 6 can face each other. At this time, the controller CNT preferably fixes (locks) the position of the bonding head 423 by the above-described fixing mechanism.

With the above-described processes, the target die 51 held by the bonding head 423 can face the wafer 6 held by the wafer stage 43 so as to obtain a state in which the bonding process for bonding the target die 51 to the target region of the wafer 6 can be executed.

In step S103, the controller CNT performs die alignment using the die observation camera 431 (see FIG. 4B). In the die alignment, the wafer stage 43 on which the die observation camera 431 mounted is driven such that the target die 51 held by the bonding head 423 is arranged above the die observation camera 431. Next, an image of the target bonding surface of the target die 51 is captured by the die observation camera 431, and the position of the pattern provided on the target bonding surface of the target die 51 is obtained based on the obtained image.

Focus adjustment when capturing an image of the target bonding surface of the target die 51 may be performed by a focus adjustment mechanism provided in the die observation camera 431, or by driving the die observation camera 431 in the Z direction by the Z driving mechanism of the wafer stage 43. When the Z driving mechanism is provided on the bonding head 423, focus adjustment may be performed by driving the target die 51 in the Z direction by the Z driving mechanism of the bonding head 423. If the alignment mark is provided on the target bonding surface of the target die 51, the position of the pattern of the target die 51 can be obtained using the alignment mark. On the other hand, for a general die, an alignment mark is often arranged on a scribe line and removed together with the scribe line. In this case, the position of the pattern of the target die 51 may be obtained using a feature point capable of specifying the position of the pattern of the target die 51. As the feature point, for example, the end of the array of pads or bumps arranged on the target bonding surface of the target die 51, a region having an aperiodic array, or the outer edge (outer shape) of the die, or the like can be used.

For example, the controller CNT can measure the position of the pattern of the target die 51 by measuring the image position of the projected alignment mark or feature point with respect to the center of the image obtained by the die observation camera 431. The measurement of the position of the target die 51 can include measurement of the rotation amount (rotation in the θZ direction) of the target die 51. The rotation amount of the target die 51 can be measured by, for example, obtaining the positions of a plurality of feature points on the target bonding surface of the target die 51 based on the image obtained by the die observation camera 431. The positions of the plurality of feature points can be obtained based on a plurality of images obtained by individually capturing the feature points while driving the die observation camera 431 by the wafer stage 43. Alternatively, when the entire target die 51 falls within the visual field of image capturing of the die observation camera 431, the positions of the plurality of feature points can be obtained from an image obtained by capturing the entire target bonding surface of the target die 51 by the die observation camera 431. The rotation amount of the target die 51 can be corrected by rotating the wafer 6 by the wafer stage 43 in the bonding process. However, the measurement range of the interferometer 422 in the rotational direction is narrow. Thus, if the rotation amount of the target die 51 is large, the target die 51 is desirably rearranged on the bonding head 423 so as to correct the rotation amount of the target die 51. When the target die 51 is rearranged on the bonding head 423, the position of the target die 51 needs to be measured again.

During execution of step S103, the surface position of the target die 51 is preferably measured using a height measurement means (not shown) that measures the surface position (height) of the target bonding surface of the target die 51. Since the thickness of the target die 51 varies, the surface position of the target die 51 is important to accurately manage (control) the gap between the wafer 6 and the target die 51 in the bonding process. Further, the heights of a plurality of points on the target bonding surface of the target die 51 (that is, the height distribution of the target bonding surface of the target die 51) may be measured to adjust the relative postures of the wafer 6 and the target die 51 based on the measurement result in the bonding process. The relative postures can be adjusted by a tilt mechanism mounted on the wafer stage 43 and/or the bonding head 423.

In step S104, the controller CNT drives the wafer stage 43 to align the wafer 6 and the target die 51 so that the pattern of the wafer 6 and the pattern of the target die 51 overlap each other (see FIG. 4C). More specifically, the controller CNT drives the wafer stage 43 so that a target region of the wafer 6 to which the target die 51 is to be bonded is arranged below the target die 51 held by the bonding head 423. The controller CNT then aligns the wafer 6 and the target die 51 based on the position of the pattern of the wafer 6 obtained in step S102 and the position of the pattern of the target die 51 obtained in step S103. At this time, it is preferable to align the wafer 6 and the target die 51 so as to reduce a relative rotation deviation and/or a posture deviation between the wafer 6 and the target die 51. If the relative position between the wafer 6 and the target die 51 is predicted to change (shift) when bonding the wafer 6 and the target die 51, the wafer 6 and the target die 51 may be aligned using the change of the relative position as an offset amount. The offset amount can be obtained in advance by experiment, simulation, or the like. The offset amount decision method (management method) will be described later.

In step S105, the controller CNT bonds the target die 51 to the wafer 6 by narrowing the interval between the wafer 6 and the target die 51 (bonding process). The bonding process may be performed by driving the target die 51 in the Z direction by the bonding head 423, or driving the wafer 6 in the Z direction by the wafer stage 43. Alternatively, the bonding process may be performed by driving the target die 51 and the wafer 6 relatively in the Z direction by the bonding head 423 and the wafer stage 43. To accurately control the interval between the wafer 6 and the target die 51, it is preferable to provide a detector (for example, an encoder) that detects the position of the bonding head 423 and/or wafer stage 43 in the Z direction and perform feedback control based on the detection result of the detector.

To improve the alignment accuracy of the wafer 6 and the target die 51 even during execution of the bonding process, the relative position between the wafer 6 and the target die 51 in the X and Y directions can be controlled. In this case, the width of the mirror 432 in the Z direction is preferably so set as to irradiate the mirror 432 with light from the interferometer 422 even if the wafer stage 43 is driven in the Z direction. Also, a detector (for example, an encoder or a gap sensor) that detects the relative position between the bonding head 423 and the wafer stage 43 in the X and Y directions may be provided. In this case, feedback control of the relative position can be performed while the detector detects (monitors) the relative position between the bonding head 423 and the wafer stage 43 in the X and Y directions during execution of the bonding process. Note that if the wafer 6 and the target die 51 come into contact with each other, the position of the wafer stage 43 feedback-controlled based on the measurement result of the interferometer 422 is restrained. Hence, the control method of the relative position between the wafer 6 and the target die 51 in the X and Y directions is preferably switched before and after contact by, for example, stopping the feedback processing at the start of contact between the wafer 6 and the target die 51.

Furthermore, in bump bonding, a process necessary for the bump bonding, such as pressing the target die 51 against the wafer 6 at a predetermined pressure (pressing pressure), may be executed in step S105. In hybrid bonding, a process of applying an impact serving as a trigger for the start of bonding may be executed in step S105. A process of observing the bonding state (bonding deviation amount) between the wafer 6 and the target die 51 after bonding may also be executed in step S105.

Here, the target die 51 is kept held by the bonding head 423 from the start of holding by the bonding head 423 in step S203 to the end of bonding between the wafer 6 and the target die 51 in step S105. That is, holding of the target die 51 by the bonding head 423 is not canceled. After bonding between the wafer 6 and the target die 51 ends in step S105, the controller CNT cancels holding of the target die 51 by the bonding head 423 and increases the interval between the wafer stage 43 and the bonding head 423. Note that it may be understood that the bonding process includes the alignment between the wafer 6 and the target die 51 in step S104 described above.

In step S106, the controller CNT determines whether the dies 51 have been bonded to all target regions on the wafer 6. Normally, several ten to several hundred semiconductor devices are formed as a plurality of target regions on one wafer 6, and the dies 51 can be bonded to the plurality of target regions. If a region (next target region) to which the die 51 is to be bonded next exists on the wafer 6, the process returns to step S202. If no next target region exists on the wafer 6, that is, the dies 51 have been bonded to all the target regions on the wafer 6, the process advances to step S107.

In this embodiment, an example in which whether the next target region exists is determined after the bonding process, and the process returns to step S202 has been explained. However, the determination of whether the next target region exists may be performed before the end of the bonding process. In this case, step S202 can be performed in parallel to execution of the bonding process. That is, in parallel to execution of the bonding process, the die 51 to be bonded to the next target region is picked up from the dicing frame 5 (dicing tape). At this time, if a plurality of bonding heads 423 and/or pickup heads 31 are provided, the parallel process can be performed more quickly. In a case where a plurality of types of dies 51 are bonded to each target region (semiconductor device) on the wafer 6, dies of one type are bonded to all the target regions of the wafer 6 and then bonding of dies of the next type starts. At the start of bonding of dies of the next type, the loading operation (step S201) of the dicing frame 5 on which dies of the next type are arranged is executed and then the die pickup in step S202 can be executed.

In step S107, using the wafer conveyance mechanism (not shown), the controller CNT unloads the wafer 6 with the dies 51 bonded to the plurality of target regions from the wafer stage 43 (wafer chuck 433). There can be considered a case where the wafer 6 is returned to the container (for example, an FOUP) used for the loading of the wafer 6 and a case where the wafer 6 is returned to a container different from the container. The wafer 6 is preferably returned to another container because the thickness of the whole wafer 6 to which the dies 51 are bonded changes, and the gap between the wafers 6 needs to be wider that for the wafers 6 before the bonding process. The operation procedure of the bonding apparatus 100A for bonding the die 51 to each of a plurality of regions on one wafer 6 has been described above. When bonding the dies 51 to each of a plurality of wafers 6, the flowchart of FIG. 3 is repeated.

Since the number of dies 51 on the dicing frame 5 and the number of the plurality of regions on the wafer 6 are generally different, loading of the wafer 6 and loading of the dicing frame 5 do not synchronize in most cases. If the dies 51 on the dicing frame 5 run out during bonding of the dies 51 to one wafer 6, the next dicing frame 5 can be loaded into the bonding apparatus 100A. If the dies 51 remain on the dicing frame 5 even after the end of bonding the dies 51 to one wafer 6, the remaining dies 51 can be used for the next wafer 6.

### [Offset Amount Decision Method]

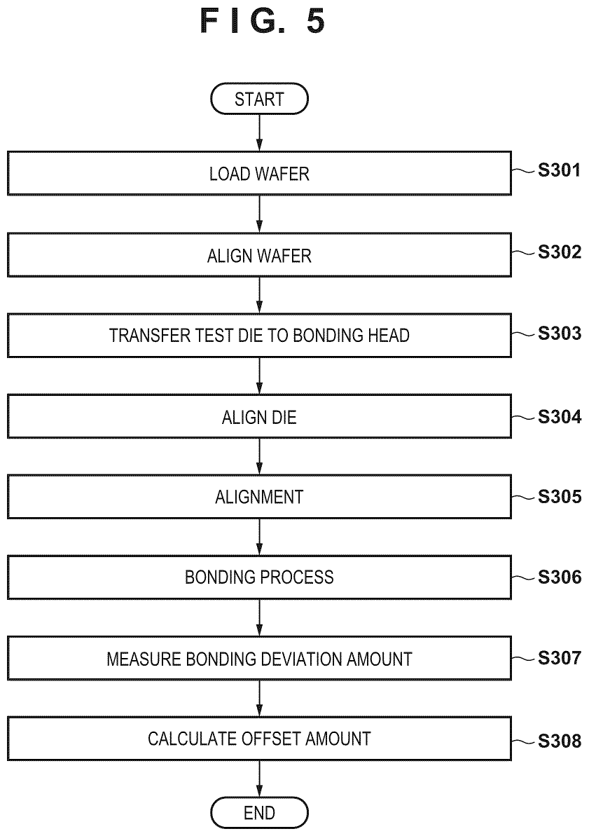

The decision method (management method) of the offset amount that can be used in step S104 described above will be described below. As described above, the offset amount can be reflected when performing alignment between the target die 51 and the target region of the wafer 6 based on the position of the target die 51 measured by the die observation camera 431 and the position of the target region of the wafer 6 measured by the wafer observation camera 421. FIG. 5 is a flowchart showing the offset amount decision method. The controller CNT can execute processes in the flowchart of FIG. 5.

Here, to decide the offset amount, a die for test (to be sometimes referred to as a test die hereinafter) can be used. The test die can be made (created) of a material that transmits measurement light detectable by the wafer observation camera 421. In this embodiment, the test die can be made of glass. If the wafer observation camera 421 can detect infrared light, the test die may be made of a material such as silicon that transmits infrared light. The test die is made in this way because the bonding deviation amount between the wafer 6 and the test die is measured by the wafer observation camera 421 after bonding of the wafer 6 (target region) and the test die. The bonding deviation amount can include, for example, the position deviation amount (that is, the overlay error) between the wafer 6 and the test die in the X and Y directions and/or the θZ direction. In addition, the test die is provided with an alignment mark used to measure the position of the die and a mark used to measure the bonding deviation amount. The test die can be produced to have a shape and pattern simulating the die 51 used in an actual process.

In step S301, the controller CNT loads the wafer 6 serving as a first object onto the wafer stage 43 (wafer chuck 433) of the bonding apparatus 100A using the wafer conveyance mechanism (not shown). On the wafer 6, a mark used for wafer alignment and a mark used to measure the bonding deviation amount are formed. The wafer 6 preferably undergoes a process such as temporary adhesive application for reducing the position deviation of the test die with respect to the wafer 6 (target region), which occurs at the time of bonding of the test die. After positions of the wafer 6 in the rotational direction and the X and Y directions are measured by a prealignment unit (not shown), the wafer 6 is coarsely positioned based on the measurement result and conveyed onto the wafer chuck 433 of the wafer stage 43. The position of the wafer 6 in the rotational direction can be measured by detecting a notch or orientation flat of the wafer 6, and the position of the wafer 6 in the X and Y directions can be measured by detecting the outer shape of the wafer 6. Note that as the wafer 6 used to decide the offset amount, a wafer for test may be used.

In step S302, the controller CNT performs wafer alignment using the wafer observation camera 421. For example, the controller CNT detects the alignment mark on the wafer 6 using the wafer observation camera 421, and measures the mount position and the rotation amount of the wafer 6 on the wafer stage 43. Step S302 is the same process as step S102 described above, and a detailed description thereof will be omitted here. During execution of step S302, the surface position of the wafer 6 is preferably measured using a height measurement means (not shown) that measures the surface position (height) of the target bonding surface of the wafer 6. This is because the thickness of the wafer 6 varies, and the surface position of the wafer 6 is important to accurately manage (control) the gap between the wafer 6 and the test die in the bonding process.

In step S303, the controller CNT mounts the test die serving as a second object on the bonding head 423. For example, test dies are arranged on a dicing tape adhered to the dicing frame 5. The dicing frame 5 is held by the frame holder 33. The controller CNT controls the pickup head 31 and the release head 32 to pick up the test die from the dicing frame 5 (dicing tape) by the pickup head 31. The controller CNT then drives the pickup head 31 to above the bonding head 423 and transfers (mounts) the test die from the pickup head 31 to the bonding head 423.

In step S304, the controller CNT performs die alignment using the die observation camera 431. For example, the controller CNT detects the alignment mark on the test die using the die observation camera 431, and measures the position and the rotation amount of the test die held by the bonding head 423. Step S304 is the same process as step S103 described above, and a detailed description thereof will be omitted here. During execution of step S304, the surface position of the test die is preferably measured using a height measurement means (not shown) that measures the surface position (height) of the target bonding surface of the test die. This is because the thickness of the test die varies, and the surface position of the test die is important to accurately manage (control) the gap between the wafer 6 and the test die in the bonding process. Further, the heights of a plurality of points on the target bonding surface of the test die may be measured to adjust the relative postures of the wafer 6 and the test die based on the measurement result in the bonding process. The relative postures can be adjusted by the tilt mechanism mounted on the wafer stage 43 and/or the bonding head 423.

In step S305, the controller CNT drives the wafer stage 43, thereby performing alignment between the wafer 6 and the test die such that the test die is arranged above the target region of the wafer 6. More specifically, the controller CNT performs alignment between the wafer 6 and the test die based on the position and the rotation amount of the wafer 6 measured in step S302 and the position and the rotation amount of the test die measured in step S304. The alignment can be performed such that the pattern (pad) of the target region of the wafer 6 and the pattern (pad) of the test die overlap each other. Step S305 is the same process as step S104 described above, and a detailed description thereof will be omitted here.

In step S306, the controller CNT bonds the test die to the wafer 6 (bonding process). Step S306 is the same process as step S105 described above, and a detailed description thereof will be omitted here.

In step S307, the controller CNT measures the bonding deviation amount between the target region of the wafer 6 and the test die using the wafer observation camera 421. For example, the controller CNT drives the wafer stage 43 such that the bonding point of the test die on the wafer 6 is arranged below the wafer observation camera 421. The controller CNT then causes the wafer observation camera 421 to capture an image of the bonding point, and measures the bonding deviation amount (the position deviation amount or the overlay error) between the wafer 6 (target region) and the test die in the X and Y directions and/or the θZ direction based on the obtained image.

An example of the mark used to measure the bonding deviation amount is a mark (Box-in-Box mark) formed by a rectangular frame having a width of 30 μm on the wafer side and a rectangular frame having a width of 60 μm on the test die side. If this mark is used, the wafer 6 and the test die are bonded such that the two frames overlap each other, and the bonding deviation amount between the wafer 6 and the test die is measured from the position deviation amount between the two frames. The mark used to measure the bonding deviation amount need not always have a rectangular shape and may have another shape such as a polygonal shape, a circular shape, or an elliptical shape other than the rectangular shape. The mark is not limited to the example in which the mark on the wafer side is the inner mark, and the mark on the die side is the outer mark, and the mark on the wafer side may be the outer mark, and the mark on the test die side may be the inner mark. Also, the mark used to measure the bonding deviation amount is not limited to the Box-in-Box mark, and the mark on the wafer side and the mark on the test die side may be arranged apart. In this case, the bonding deviation amount may be measured based on the interval between the mark on the wafer side and the mark on the test die side (for example, the deviation from a target interval). The bonding deviation amount is preferably measured at a plurality of points of the test die. When bonding deviation amount is measured at a plurality of points, not only the bonding deviation amount in the X and Y directions but also the bonding deviation amount in the θZ direction (that is, the rotation error) can be measured. In addition, when statistical processing is performed for the bonding deviation amounts at the plurality of points, it is possible to reduce measurement errors and accurately measure the bonding deviation amount.

In step S308, the controller CNT calculates an offset amount based on the bonding deviation amount measured in step S307. For example, the controller CNT calculates, as the offset amount, the position deviation amount in the X and Y directions and the rotation amount in the θZ direction for reducing the bonding deviation amount measured in step S307. In the above description, the offset amount is calculated for one region of the wafer 6 to which one test die is bonded. However, it is preferable to calculate the offset amount for each of a plurality of regions on the wafer 6 using a plurality of test dies. The plurality of regions on the wafer 6 are preferably set to positions corresponding to a plurality of regions to which a plurality of dies 51 are bonded in the actual process. Also, the representative value of the offset amounts calculated for the plurality of regions on the wafer 6 may commonly be used in the plurality of regions. Examples of the representative value are an average value, a maximum value, and a mode. If the offset amount changes in accordance with the position of the wafer 6, the offset amount may individually be calculated for each of the plurality of regions on the wafer 6.

An example in which alignment between the wafer 6 and the target die 51 is performed in step S104 of FIG. 3 using the offset amount calculated in the above-described way will be described here. Note that signs change depending on the manner the direction of coordinates is defined, but comply with the coordinate system shown in each drawing in the following example.

Let (Wx, Wy) be the position of the target region of the wafer 6 measured in step S102 with respect to a reference point, and Wθ be the rotation amount. Let (Dx, Dy) be the position of the target die 51 with respect to the center of gravity (center) of the image obtained by the die observation camera 431 in step S103, and DO be the rotation amount. Let (Px, Py) be the amount of the shift (shift amount) of the wafer 6 and the target die 51 when bonding the wafer 6 and the target die 51, and PO be the rotation amount. Also, as the offset amount obtained in step S308, let (X0, Y0) be the position deviation amount in the X and Y directions, and θ0 be the rotation amount in the θZ direction.

If the offset amount is correctly obtained in step S308, Wx=Wy=Wθ=Dx=Dy=Dθ=0. For this reason, when bonding the target die 51 to the wafer 6, alignment between the wafer 6 and the target die 51 is performed in step S104 such that the target die 51 deviates by the offset amount with respect to the target region of the wafer 6. That is, the wafer stage 43 is arranged such that the position deviation amount in the X and Y directions is (X0, Y0), and the rotation amount in the θZ direction is θ0, and the target die 51 is bonded to the wafer 6. This makes it possible to accurately perform the bonding process at a high position accuracy.

If the position of the wafer 6 is deviated in the bonding process, for example, if the position of the wafer 6 is deviated in the positive direction, the wafer stage 43 is moved in the negative direction, thereby correcting the deviation of the wafer 6. More specifically, in the bonding process, the wafer stage 43 is arranged such that the position deviation amount in the X and Y directions is (X0−Wx, Y0−Wy), and the rotation amount in the θZ direction is (θ0−Wθ).

If the position of the target die 51 is deviated in the bonding process, for example, if the position of the target die 51 is deviated in the positive direction, the wafer stage 43 is moved in the positive direction, thereby correcting the deviation of the target die 51. More specifically, in the bonding process, the wafer stage 43 is arranged such that the position deviation amount in the X and Y directions is (X0θWx+Dx, Y0−Wy+Dy), and the rotation amount in the θZ direction is (θ0−Wθ+Dθ).

If a shift amount is generated in the bonding process, a position shifted by the amount is set to the bonding position. For example, if the shift amount is generated in the positive direction, the wafer stage 43 is moved by the same amount, and the bonding process is then performed. More specifically, in the bonding process, the wafer stage 43 is arranged such that the position deviation amount in the X and Y directions is (X0−Wx+Dx+Px, Y0−Wy+Dy+Py), and the rotation amount in the θZ direction is (θ0−Wθ+Dθ+Pθ).

As described above, the bonding apparatus 1θ0A according to this embodiment includes the surface treatment unit 46 that performs surface treatment of the target bonding surface of the die 51 in a state in which the die 51 is held by the bonding head 423. In the bonding apparatus 1θ0A, after the surface treatment is performed by the surface treatment unit 46, the bonding process of aligning the wafer 6 and the die 51 and bonding the die 51 to the wafer 6 is performed without canceling holding of the die 51 by the bonding head 423. This makes it possible to avoid another member from contacting the target bonding surface of the die 51 between the surface treatment and the bonding process, shorten the time from the surface treatment to the bonding process, and improve the bonding strength between the wafer 6 and the die 51.

### Second Embodiment

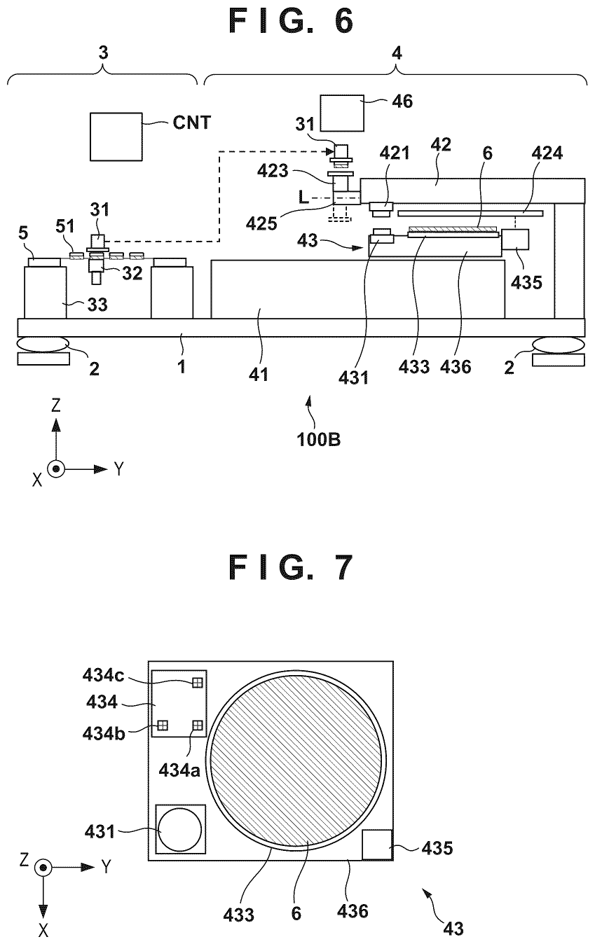

The second embodiment according to the present invention will be described. FIG. 6 is a schematic view showing a bonding apparatus 1θ0B according to the second embodiment. The bonding apparatus 1θ0B according to this embodiment measures the position of a wafer stage using an encoder, as shown in FIG. 6. Note that the second embodiment basically inherits the first embodiment and can comply with the first embodiment except matters mentioned below.

The bonding apparatus 1θ0B according to the second embodiment is different from the bonding apparatus 1θ0A according to the first embodiment shown in FIG. 1 in that an encoder scale 424 and an encoder head 435 are provided in place of the interferometer 422 and the bar mirror 432. In the bonding apparatus 1θ0B according to the second embodiment, the encoder head 435 is provided on a wafer stage 43, and the encoder scale 424 is mounted on an upper base 42. In the encoder scale 424, a two-dimensional scale is formed on a plane such that two-dimensional positioning can be performed. The position of the wafer stage 43 can two-dimensionally be measured by detecting the scale by the encoder head 435. It is preferable that the encoder scale 424 has a low thermal expansion coefficient, and the scale is formed (drawn) at a high position accuracy. As an example of the encoder scale 424, the scale is drawn on a quartz substrate using the drawing method of a semiconductor lithography process. Here, the wafer stage 43 may be constituted by a coarse motion stage that can be driven within a large range, and a fine motion stage that can accurately be driven within a small range on the coarse motion stage. In this case, to perform accurate positioning, the encoder head 435 is preferably fixed to the fine motion stage. The positioning means according to this embodiment includes accurate position measurement by the encoder and feedback control based on the result. Note that a unit formed by the encoder scale 424 and the encoder head 435 will sometimes be referred to as an “encoder” hereinafter.

A method of guaranteeing the origin position, magnification, the X-axis and Y-axis directions (rotation), and the orthogonality of the stage using a reference plate 434 will be described next with reference to FIG. 7. FIG. 7 is a view showing the wafer stage 43 from the +Z direction. While controlling a wafer observation camera 421 to capture (observe) an image of a mark 434a, a controller CNT obtains the measured value of the encoder when the mark 434a is arranged at the center of the image obtained by the wafer observation camera 421, and sets the measured value as the origin of the wafer stage 43. Then, while controlling the wafer observation camera 421 to capture (observe) an image of a mark 434b, the controller CNT obtains the measured value of the encoder when the mark 434b is arranged at the center of the image obtained by the wafer observation camera 421. From the obtained measured value, the controller CNT decides the Y-axis direction and Y magnification of the wafer stage 43. Next, while controlling the wafer observation camera 421 to capture (observe) an image of a mark 434c, the controller CNT obtains the measured value of the encoder when the mark 434c is arranged at the center of the image obtained by the wafer observation camera 421. From the obtained measured value, the controller CNT decides the X-axis direction and × magnification of the wafer stage 43. That is, a direction from the mark 434b toward the mark 434a on the reference plate 434 is defined as the Y-axis of the bonding apparatus 1θ0B, a direction from the mark 434c toward the mark 434a is defined as the X-axis of the bonding apparatus 1θ0B, and the directions and orthogonality of the axes are calibrated. Also, the interval between the mark 434b and the mark 434a is defined as the scale reference of the bonding apparatus 1θ0B in the Y direction, the interval between the mark 434c and the mark 434a is defined as the scale reference of the bonding apparatus 1θ0B in the X direction, and calibration is performed. Since the scale of the encoder thermally expands due to variations of the temperature, and the measured values are different from the actual values (distances), it is preferable that calibration is performed at an arbitrary timing to guarantee the origin position, magnification, rotation, and orthogonality of the wafer stage 43.

Here, the encoder may include a linear encoder for each driving stage. In this case, since variation factors increase between the wafer stage 43 and the measurement point of the encoder, a contrivance of, for example, raising the frequency of calibration or using another measurement method is necessary. If a plurality of encoder heads 435 are arranged and selectively used in accordance with, for example, the bonding position, the footprint of the bonding apparatus 1θ0B can be made small. Alternatively, if a plurality of encoder heads 435 are arranged at positions symmetrically sandwiching the bonding position, and measured values from the plurality of encoder heads 435 are used, the position measurement accuracy of the wafer stage 43 can be improved. In the above description, an example in which calibration is performed by capturing (observing) an image of the reference plate 434 has been described, but the present invention is not limited to this. For example, calibration may be performed by an abutting operation to a reference surface. Alternatively, accurate positioning may be performed by providing a calibration mechanism in the encoder and using a position measurement means for which an absolute value is guaranteed.

The bonding apparatus 1θ0B configured as described above operates like the bonding apparatus 1θ0A according to the first embodiment. That is, in the bonding apparatus 1θ0B as well, a die 51 is bonded to each of a plurality of regions on a wafer 6 in accordance with the flowchart of FIG. 3. In the bonding apparatus 1θ0B, however, for example, in step S104 of FIG. 3, alignment between the wafer 6 and the die 51 can be controlled based on the measured value of the encoder.

### Third Embodiment

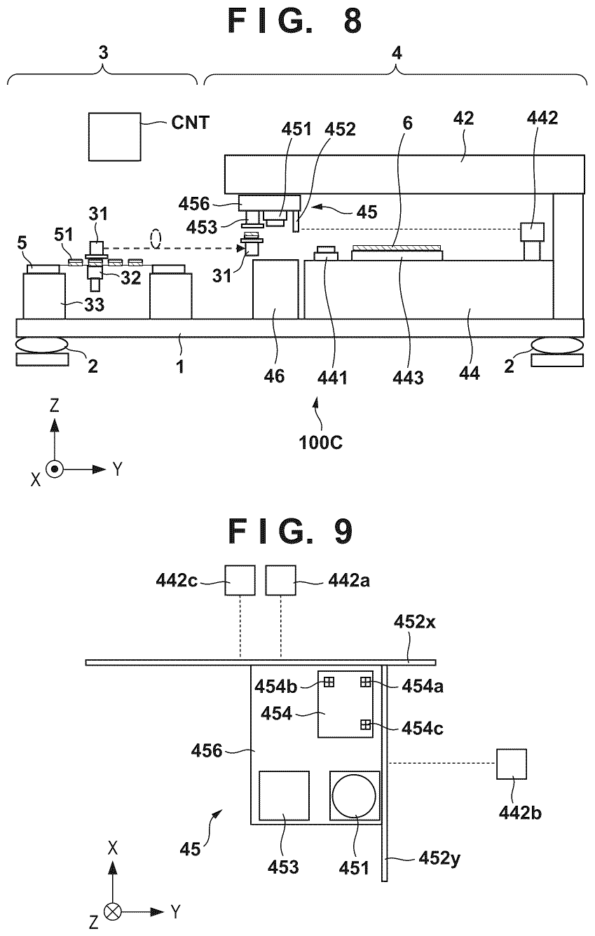

The third embodiment according to the present invention will be described. FIG. 8 is a schematic view showing a bonding apparatus 100C according to the third embodiment. As shown in FIG. 8, the bonding apparatus 100C according to this embodiment drives a bonding head that holds a die, instead of driving a wafer stage 43 that holds a wafer, thereby aligning the wafer and the die and bonding the die to the wafer. In FIG. 8, a direction vertical to the upper surface (target bonding surface) of a wafer 6 held by a wafer chuck 443 is defined as the Z direction, and directions orthogonal to each other in a plane parallel to the upper surface of the wafer 6 are defined as the X direction and the Y direction. Note that the third embodiment basically inherits the first embodiment and can comply with the first embodiment except matters mentioned below. The same reference numerals as in the first embodiment denote the same elements in the third embodiment, and a detailed description of the elements will be omitted. In the third embodiment, a configuration example in which the bonding head (die 51) is driven will be described. However, in addition the bonding head, the wafer 6 may be driven, as in the first embodiment. In this case, the second embodiment may be applied.

The bonding apparatus 100C according to this embodiment includes a pickup unit 3, a bonding unit 4, and a controller CNT, as shown in FIG. 8. The pickup unit 3 and the controller CNT are the same as those in the bonding apparatus 1θ0A according to the first embodiment, and a detailed description thereof will be omitted here.

The bonding unit 4 includes an upper base 42 and a lower base 44, and a surface treatment unit 46 is provided on a side of the lower base 44. The surface treatment unit 46 (treatment unit) performs surface treatment for the held surface of the die 51 in a state in which the die 51 is held by a bonding head 453 such that the die 51 is arranged at the surface treatment position (such that the target bonding surface of the die 51 faces down). As described above in the first embodiment, the surface treatment unit 46 includes, for example, an atmospheric pressure plasma activation device and executes, as the surface treatment, an activation treatment of activating the surface state of the held surface of the die 51. Also, the surface treatment unit 46 may include a washing device and executes, as the surface treatment, a washing treatment of washing the held surface of the die 51. The surface treatment unit 46 may include a lyophilic device and executes, as the surface treatment, a lyophilic treatment of making the held surface of the die 51 lyophilic (hydrophilic).

A bonding stage 45 is mounted on the upper base 42. The bonding stage 45 is configured to move in the X and Y directions along the lower surface of the upper base 42. More specifically, the bonding stage 45 includes a bonding head 453 that holds the die 51, and a driving unit 456 that drives the bonding head 453 (die 51).

The bonding head 453 holds the die 51 transferred from a pickup head 31 by a vacuum suction force or the like. In this embodiment, the pickup head 31 picks up one die 51 from a dicing tape adhered to a dicing frame 5 and moves it from the pickup unit 3 to the bonding unit 4. The target bonding surface of the die 51 picked up from the dicing tape by the pickup head 31 faces up. That is, the target bonding surface of the die 51 is held by the pickup head 31. For this reason, during movement from the pickup unit 3 to the bonding unit 4, the pickup head 31 rotates (flips) to turn the die 51 upside down and transfers it to the bonding head 453. The bonding head 453 can thus hold the die 51 while keeping the held surface of the die 51 face down.

In this embodiment, since the surface treatment is performed in a state in which the die 51 is held by the bonding head 453, the holding surface of the bonding head 453 for the die 51 is preferably made of a material hard to be damaged by the surface treatment. Bonding of the die 51 to the wafer 6 can be done by relatively driving the die 51 and the wafer 6 by the bonding head 453 and the wafer chuck 443 (wafer stage). Bonding of the die 51 to the wafer 6 may be performed by driving the die 51 in the −Z direction by the bonding head 453 or by driving the wafer 6 in the +Z direction by the wafer chuck 443 (wafer stage).

The driving unit 456 includes an actuator such as a linear motor, and is configured to drive the bonding head 453 (die 51) in the X and Y directions and the θZ direction. The driving unit 456 may be configured to drive the bonding head 453 (die 51) in the Z direction. A relative rotational operation of the wafer 6 and the die 51 in the θZ direction can be performed by rotating the die 51 by the bonding stage 45 (driving unit 456) and/or rotating the wafer 6 by the wafer chuck 443 (wafer stage).

The driving unit 456 drives the bonding head 453, thereby moving the die 51 between a surface treatment position at which surface treatment of the target bonding surface of the die 51 is performed by the surface treatment unit 46 and a bonding process position at which a bonding process of bonding the die 51 to the wafer 6 is performed. That is, the driving unit 456 switches the position of the die 51 between the surface treatment position and the bonding process position. In this embodiment, the direction of the target bonding surface of the die 51 faces down at both the surface treatment position (first position) and the bonding process position (second position). Hence, the driving unit 456 is configured to translationally drive the bonding head 453 in the Y directions. This makes it possible to move the die 51 between the surface treatment position and the bonding process position such that the target bonding surface of the die 51 faces in the same direction at the surface treatment position and the bonding process position.

The bonding stage 45 is provided with a mirror 452 for measuring the position of the bonding stage 45 in the X and Y directions. The mirror 452 serves as the target of an interferometer 442 that measures the position of the bonding stage 45 in the X and Y directions. The interferometer 442 is mounted on the lower base 44, irradiates the mirror 452 provided on the bonding stage 45 with light, and measures the position of the bonding stage 45 based on reflected light from the mirror 452. The controller CNT can control the position of the bonding stage 45 (die 51) in the X and Y directions and the θZ direction based on the position of the bonding stage 45 measured by the interferometer 442.

Also, a wafer observation camera 451 (wafer image capturing device) is mounted on the bonding stage 45. The wafer observation camera 451 is a camera for observing the target bonding surface of the wafer 6. The wafer observation camera 451 can be arranged so that it can capture an image of the wafer 6 in a state in which the wafer 6 is held by the wafer chuck 443 (wafer stage). The wafer observation camera 451 is used to obtain (measure) information representing the position of a pattern provided on the target bonding surface of the wafer 6. For example, using a known image processing technique, the controller CNT detects the position of a feature point on the target bonding surface of the wafer 6 from an image obtained by capturing the target bonding surface of the wafer 6 by the wafer observation camera 451. Thus, the controller CNT can measure the position of the pattern of the wafer 6 held by the wafer chuck 443 (wafer stage) in the X and Y directions and/or the θZ direction.

Mechanisms mounted on the lower base 44 will be described next. A die observation camera 441 and the wafer chuck 443 are mounted on the lower base 44. The wafer chuck 443 holds the wafer 6 (substrate) by a vacuum suction force or the like, and may be understood as a wafer stage.

The die observation camera 441 (die image capturing device) is a camera for observing the target bonding surface of the die 51. The die observation camera 441 can be arranged so that it can capture an image of the target bonding surface of the die 51 in a state in which the die 51 is held by the bonding head 453, and the target bonding surface of the die 51 faces down. In this embodiment, when the bonding stage 45 moves to arrange the die 51 held by the bonding head 453 above the die observation camera 441, an image of the target bonding surface of the die 51 is captured (observed) by the die observation camera 441. The die observation camera 441 is used to obtain (measure) information representing the position of a pattern provided on the target bonding surface of the die 51. For example, using a known image processing technique, the controller CNT detects the position of a feature point on the target bonding surface of the die 51 from an image obtained by capturing the target bonding surface of the die 51 by the die observation camera 441. Thus, the controller CNT can measure the position of the pattern of the die 51 held by the bonding head 453 in the X and Y directions and/or the θZ direction.

Here, the relative position between the wafer observation camera 451 and the die observation camera 441 is preferably calibrated to accurately reduce a bonding deviation between the wafer 6 and the die 51 in the bonding process. Hence, for the calibration, marks observable by one or both of the wafer observation camera 451 and the die observation camera 441 are preferably arranged (mounted) on the bonding apparatus 100C.

A detailed example of the configuration of the bonding stage 45 will be described next. FIG. 9 is a view showing the bonding stage 45 viewed from the −Z direction. The bonding head 453 holds the die 51. To perform two-dimensional positioning, the bonding stage 45 includes a bar mirror 452x for performing position measurement in the X direction and the θZ direction, and a bar mirror 452y for performing position measurement in the Y direction. The bar mirror 452x is the target of interferometers 442a and 442c that perform position measurement in the X direction. The interferometers 442a and 442c are arranged apart in the Y direction. The rotational amount (θZ direction) of the bonding stage 45 can be obtained from the difference between the measurement result of the interferometer 442a and that of the interferometer 442c. The bar mirror 452y is the target of an interferometer 442b that performs position measurement in the Y direction. The interferometers 442a to 442c measure in real time the position of the bonding stage 45 in the X direction, the position in the Y direction, and the rotational amount in the θZ direction. The controller CNT can perform feedback control of driving of the bonding stage 45 in real time and two-dimensionally position the bonding stage 45 accurately. In the bonding apparatus 100C according to this embodiment, accurate position measurement by the interferometers 442a to 442c, and feedback control of the bonding stage 45 based on the result of the position measurement can function as the positioning mechanism of the bonding stage 45.

A reference plate 454 including a plurality of marks 454a to 454c is mounted on the bonding stage 45. The reference plate 454 is made of a material with a low thermal expansion coefficient, and includes the marks 454a to 454c formed (drawn) at a high position accuracy. For example, the reference plate 454 can be formed by drawing marks on a quartz substrate using the drawing method of a semiconductor lithography process. The reference plate 454 can be arranged to have a surface substantially flush with the surface of the die 51 held by the bonding head 453. In this embodiment, the reference plate 454 can be observed by the die observation camera 441, but the present invention is not limited to this when a reference plate observation camera is separately provided. The bonding stage 45 may be constituted by a coarse motion stage that can be driven within a large range, and a fine motion stage that can accurately be driven within a small range on the coarse motion stage. In this case, the wafer observation camera 451, the bar mirror 452, the bonding head 453, and the reference plate 454 require accurate positioning and thus are preferably fixed to the fine motion stage.

A method of guaranteeing the origin position, magnification, the X-axis and Y-axis directions (rotation), and the orthogonality of the bonding stage 45 using the reference plate 454 will be described. While controlling the die observation camera 441 to capture (observe) an image of the mark 454a, the controller CNT obtains the measured values of the interferometers 442a to 442c when the mark 454a is arranged at the center of the image obtained by the die observation camera 441. The obtained measured values are set as the origin of the bonding stage 45. Then, while controlling the die observation camera 441 to capture (observe) an image of the mark 454b, the controller CNT obtains the measured values of the interferometers 442a to 442c when the mark 454b is arranged at the center of the image obtained by the die observation camera 441. From the obtained measured values, the controller CNT decides the Y-axis direction and Y magnification of the bonding stage 45. Next, while controlling the die observation camera 441 to capture (observe) an image of the mark 454c, the controller CNT obtains the measured values of the interferometers 442a to 442c when the mark 454c is arranged at the center of the image obtained by the die observation camera 441. From the obtained measured values, the controller CNT decides the X-axis direction and × magnification of the bonding stage 45. That is, a direction from the mark 454b toward the mark 454a on the reference plate 454 is defined as the Y-axis of the bonding apparatus 100C, a direction from the mark 454c toward the mark 454a is defined as the X-axis of the bonding apparatus 100C, and the directions and orthogonality of the axes are calibrated. Also, the interval between the mark 454b and the mark 454a is defined as the scale reference of the bonding apparatus 100C in the Y direction, the interval between the mark 454c and the mark 454a is defined as the scale reference of the bonding apparatus 100C in the X direction, and calibration is performed. The refractive index of the optical path of the interferometer changes due to variations of the atmospheric pressure and temperature, this makes the measured value vary, and thus it is preferable for the interferometers 442a to 442c to perform calibration at an arbitrary timing and guarantee the origin position, magnification, rotation, and orthogonality of the bonding stage 45. Note that to reduce variations of the measured values of the interferometers 442a to 442c, the space in which the bonding stage 45 moves may be covered with a temperature control chamber to control the temperature.

In this embodiment, an example in which the reference plate 454 is arranged on the bonding stage 45 and an image of the reference plate 454 is captured (observed) by the die observation camera 441 has been described, but the present invention is not limited to this. For example, the reference plate 454 may be arranged on the lower base 44 to capture (observe) an image of the reference plate 454 by the wafer observation camera 451. Even in this configuration, the origin position, magnification, rotation, and orthogonality of the bonding stage 45 can be guaranteed. In this embodiment, an example in which calibration is performed by capturing (observing) an image of the reference plate 454 has been described, but the present invention is not limited to this. For example, calibration may be performed by an abutting operation to a reference surface. Alternatively, accurate positioning of the bonding stage 45 may be performed using a position measurement means such as a white interferometer for which an absolute value is guaranteed. Also, in this embodiment, correction of an Abbe error is important because the position where bonding is performed (bonding process position) and the point measured by an interferometer 442 are apart. It is also possible to reduce errors by performing measurement on both sides of the bonding stage 45.

### [Operation of Bonding Apparatus]

The operation (bonding method) of the bonding apparatus 100C according to this embodiment will be described below. The operation of the bonding apparatus 100C according to this embodiment can be performed in accordance with the flowchart of FIG. 3. Matters different from the first embodiment will be described below, and a description of the same matters as in the first embodiment will be omitted.

In step S101, the controller CNT loads the wafer 6 serving as a first object onto the wafer chuck 443 (wafer stage) of the bonding apparatus 100C using a wafer conveyance mechanism (not shown). After positions of the wafer 6 in the rotational direction and the X and Y directions are measured by a prealignment unit (not shown), the wafer 6 is coarsely positioned based on the measurement result and conveyed onto the wafer chuck 443.

In step S102, the controller CNT performs wafer alignment using the wafer observation camera 451. In the wafer alignment, the wafer observation camera 451 captures an image of the target bonding surface of a target region (bonding target) to which the die 51 is to be bonded in a plurality of regions of the wafer 6. Based on the obtained image, the position of a pattern provided on the target region is obtained. Focus adjustment when capturing an image of the target bonding surface of the wafer 6 may be performed by a focus adjustment mechanism provided in the wafer observation camera 451, or by driving the wafer 6 in the Z direction by the Z driving mechanism of the wafer chuck 443. When an alignment mark is provided on the target bonding surface of the wafer 6, the position of the pattern of the wafer 6 can be obtained using the alignment mark. To the contrary, when no alignment mark is provided on the target bonding surface of the wafer 6, the position of the pattern of the wafer 6 may be obtained using a feature point capable of specifying the position of the pattern of the wafer 6. As the feature point, for example, part of the pattern of the wafer 6 can be used.

For example, the controller CNT can measure the position of the pattern of the wafer 6 by measuring the image position of a projected alignment mark or feature point with respect to the center of the image obtained by the wafer observation camera 451. The alignment mark or feature point will be sometimes referred to as an alignment mark or the like. For example, there is a method of accurately measuring the position of the alignment mark or the like with respect to the reference point of the bonding apparatus 100C. According to this method, the bonding stage 45 is driven in advance to make a mark formed on the reference plate 454 fall within the visual field of image capturing of the die observation camera 441, and the die observation camera 441 captures an image of the mark on the reference plate 454. Based on the position of the bonding stage 45 at that time and the mark position within the image obtained by the die observation camera 441, the reference point of the bonding apparatus 100C is decided. Based on the image obtained by capturing the alignment mark or the like by the wafer observation camera 451, the offset amount of the position of the alignment mark or the like with respect to the reference point is obtained. Hence, the position of the alignment mark can be measured accurately from the position of the reference point and the offset amount. As the position of the reference point of the bonding apparatus 100C, the position of the specific mark on the reference plate 454 is used in this embodiment. However, the position of another place may be used if it is a position serving as a reference.

Since the interferometer 442 has a narrow measurement range in the rotational direction, a rotation amount that can be corrected by the bonding stage 45 is relatively small. If the rotation amount of the wafer 6 is large, the wafer 6 is preferably rearranged on the wafer chuck 443 so as to correct the rotation amount of the wafer 6. When the wafer 6 is rearranged on the wafer chuck 443, the position of the wafer 6 needs to be measured again. During execution of step S102, the surface position of the wafer 6 is preferably measured using a height measurement means (not shown) that measures the surface position (height) of the target bonding surface of the wafer 6. This is because the thickness of the wafer 6 varies, and the surface position of the wafer 6 is important to accurately manage (control) the gap between the wafer 6 and the die 51 in the bonding process.

The origin position, the magnification, the X-axis and Y-axis directions (rotation), and the orthogonality are guaranteed for the bonding stage 45 using the reference plate 454. For this reason, the position of the wafer 6 mounted on the wafer chuck 443 with respect to the origin position of the bonding stage 45 and the like can be measured. On the wafer 6, regions (bonding targets or target regions) where semiconductor devices (patterns) are formed are repetitively arranged at a predetermined period, as described above in the first embodiment. That is, the wafer 6 includes a plurality of regions to which the dies 51 are bonded, respectively. A semiconductor device in each region of the wafer 6 is accurately positioned and manufactured using a semiconductor manufacturing apparatus. A plurality of regions on the wafer 6 are accurately arrayed generally at a repetitive period with a nano-level accuracy. For this reason, in the wafer alignment of step S102, it is not necessary to measure the positions of all regions on the wafer 6, and it is only necessary to measure the positions of some of the plurality of regions on the wafer 6. More specifically, the positions of semiconductor devices (patterns or marks) in three or more regions out of a plurality of regions on the wafer 6 are measured, and statistical processing is performed. Accordingly, the array of regions on the wafer 6, the origin position of the array, the position in the X and Y directions, the rotation amount in the θZ direction, the orthogonality, and the magnification error of the repetitive period can be calculated. Also, like the wafer chuck 433 according to the first embodiment, the wafer chuck 443 according to this embodiment may also be provided with a mechanism configured to control the temperature of the wafer 6.

Note that in this embodiment, the wafer 6 is used as the first object. If an interposer on which wirings are formed is used as the first object, not the array of semiconductor devices but the array of the repetitively formed wirings is measured. If a wafer or panel without a pattern is used as the first object, wafer alignment in step S102 need not be executed.

In parallel to steps S101 and S102 which are processes regarding the wafer 6 that is the first object, processes (steps S201 to S205) regarding the die 51 that is the second object are executed. Note that steps S201 and S202 are the same as described in the first embodiment, and a detailed description thereof will be omitted here.

In step S203, the controller CNT transfers (delivers) the target die 51 picked up by the pickup head 31 to the bonding head 453 of the bonding unit 4. More specifically, the controller CNT drives the pickup head 31 picking up the target die 51 in the X direction and performs a flip operation (inverting operation), thereby arranging the pickup head 31 below the bonding head 453. At this time, the bonding head 453 is driven (positioned) by the driving unit 456 such that the holding surface for holding the target die 51 faces down. The controller CNT then transfers the target die 51 from the pickup head 31 to the bonding head 453 by driving the pickup head 31 in the +Z direction.

In this embodiment, an example in which the pickup head 31 directly conveys the target die 51 to the bonding head 453 has been described, but the present invention is not limited to this. For example, when one or more conveyance mechanisms are provided on the conveyance path of the target die 51 to the bonding head 453, the target die 51 may be conveyed to the bonding head 453 through a process of transferring the target die 51 to the one or more conveyance mechanisms. Also, if one or more die holders are provided in the conveyance path of the target die 51 to the bonding head 453, the pickup head 31 may convey the target die 51 to the bonding head 453 after the target die 51 is re-held using the one or more die holders.

In step S204, the controller CNT causes the surface treatment unit 46 to execute surface treatment for the target bonding surface of the target die 51 held by the bonding head 453. At this time, the bonding head 453 is driven (positioned) by the driving unit 456 such that the target die 51 is arranged at the surface treatment position (more specifically, above the surface treatment unit 46). In this embodiment, the surface treatment for the held surface of the target die 51 can be performed in a state in which the target bonding surface of the target die 51 faces down. As described above, the surface treatment includes an activation treatment, and may additionally include a washing treatment and/or lyophilic treatment.

In step S205, the controller CNT causes the bonding stage 45 (driving unit 456) to translationally drive the bonding head 453 in the +Y direction such that the target die 51 held by the bonding head 453 is arranged at the bonding process position. The target bonding surface of the target die 51 held by the bonding head 453 can thus face the target bonding surface of the wafer 6.

In step S103, the controller CNT performs die alignment using the die observation camera 441. In the die alignment, the bonding stage 45 is driven such that the target die 51 held by the bonding head 453 is arranged above the die observation camera 441. Next, an image of the target bonding surface of the target die 51 is captured by the die observation camera 441, and the position of the pattern provided on the target bonding surface of the target die 51 is obtained based on the obtained image.

Focus adjustment when capturing an image of the target bonding surface of the target die 51 may be performed by a focus adjustment mechanism provided in the die observation camera 441, or by driving the bonding head 453 (target die 51) in the Z direction by the Z driving mechanism of the bonding stage 45. If an alignment mark is provided on the target bonding surface of the target die 51, the position of the pattern of the target die 51 can be obtained using the alignment mark. On the other hand, for a general die, an alignment mark is often arranged on a scribe line and removed together with the scribe line. In this case, the position of the pattern of the target die 51 may be obtained using a feature point capable of specifying the position of the pattern of the target die 51. As the feature point, for example, the end of the array of pads or bumps arranged on the target bonding surface of the target die 51, a region having an aperiodic array, or the outer edge (outer shape) of the die, or the like can be used.

For example, the controller CNT can measure the position of the pattern of the target die 51 by measuring the image position of the projected alignment mark or feature point with respect to the center of the image obtained by the die observation camera 441. The measurement of the position of the target die 51 can include measurement of the rotation amount (rotation in the θZ direction) of the target die 51. The rotation amount of the target die 51 can be measured by, for example, obtaining the positions of a plurality of feature points on the target bonding surface of the target die 51 based on the image obtained by the die observation camera 441. The positions of the plurality of feature points can be obtained based on a plurality of images obtained by individually capturing the feature points by the die observation camera 441 while driving the target die 51 by the bonding stage 45. Alternatively, when the entire target die 51 falls within the visual field of image capturing of the die observation camera 441, the positions of the plurality of feature points can be obtained from an image obtained by capturing the entire target bonding surface of the target die 51 by the die observation camera 441. The rotation amount of the target die 51 can be corrected by rotating the target die 51 by the bonding stage 45 in the bonding process. However, the measurement range of the interferometer 442 in the rotational direction is narrow. Thus, if the rotation amount of the target die 51 is large, the target die 51 is desirably rearranged on the bonding head 453 so as to correct the rotation amount of the target die 51. When the target die 51 is rearranged on the bonding head 453, the position of the target die 51 needs to be measured again.

During execution of step S103, the surface position of the target die 51 is preferably measured using a height measurement means (not shown) that measures the surface position (height) of the target bonding surface of the target die 51. Since the thickness of the target die 51 varies, the surface position of the target die 51 is important to accurately manage (control) the gap between the wafer 6 and the target die 51 in the bonding process. Further, the heights of a plurality of points on the target bonding surface of the target die 51 (that is, the height distribution of the target bonding surface of the target die 51) may be measured to adjust the relative postures of the wafer 6 and the target die 51 based on the measurement result in the bonding process. The relative postures can be adjusted by a tilt mechanism mounted on the bonding stage 45 and/or the wafer chuck 443.

In step S104, the controller CNT drives the bonding stage 45 to align the wafer 6 and the target die 51 so that the pattern of the wafer 6 and the pattern of the target die 51 overlap each other. More specifically, the controller CNT drives the bonding stage 45 so that the target die 51 held by the bonding head 453 is arranged above a target region of the wafer 6 to which the target die 51 is to be bonded. The controller CNT then aligns the wafer 6 and the target die 51 based on the position of the pattern of the wafer 6 obtained in step S102 and the position of the pattern of the target die 51 obtained in step S103. At this time, it is preferable to align the wafer 6 and the target die 51 so as to reduce a relative rotation deviation and/or a posture deviation between the wafer 6 and the target die 51. If the relative position between the wafer 6 and the target die 51 is predicted to change (shift) when bonding the wafer 6 and the target die 51, the wafer 6 and the target die 51 may be aligned using the change of the relative position as an offset amount. The offset amount can be obtained in advance by experiment, simulation, or the like. The offset amount decision method (management method) will be described later.

In step S105, the controller CNT bonds the target die 51 to the wafer 6 by narrowing the interval between the wafer 6 and the target die 51 (bonding process). The bonding process may be performed by driving the target die 51 in the Z direction by the bonding head 453, or driving the wafer 6 in the Z direction by the wafer chuck 443. Alternatively, the bonding process may be performed by driving the target die 51 and the wafer 6 relatively in the Z direction by the bonding head 453 and the wafer chuck 443. To accurately control the interval between the wafer 6 and the target die 51, it is preferable to provide a detector (for example, an encoder) that detects the position of the bonding head 453 and/or wafer chuck 443 in the Z direction and perform feedback control based on the detection result of the detector.

To improve the alignment accuracy of the wafer 6 and the target die 51 even during execution of the bonding process, the relative position between the wafer 6 and the target die 51 in the X and Y directions can be controlled. In this case, the width of the mirror 452 in the Z direction is preferably so set as to irradiate the mirror 452 with light from the interferometer 442 even if the bonding stage 45 is driven in the Z direction. Also, a detector (for example, an encoder or a gap sensor) that detects the relative position between the bonding head 453 and the wafer chuck 443 in the X and Y directions may be provided. In this case, feedback control of the relative position can be performed while the detector detects (monitors) the relative position between the bonding head 453 and the wafer chuck 443 in the X and Y directions during execution of the bonding process. To accurately control the interval between the target die 51 and the wafer 6, a measurement unit (for example, a linear encoder) configured to measure the relative position between the bonding head 453 and the wafer chuck 443 in the Z direction may be provided. Note that if the wafer 6 and the target die 51 come into contact with each other, the position of the bonding stage 45 feedback-controlled based on the measurement result of the interferometer 442 is restrained. Hence, the control method of the relative position between the wafer 6 and the target die 51 in the X and Y directions is preferably switched before and after contact by, for example, stopping the feedback processing at the start of contact between the wafer 6 and the target die 51.

Furthermore, in bump bonding, a process necessary for the bump bonding, such as pressing the target die 51 against the wafer 6 at a predetermined pressure (pressing pressure), may be executed in step S105. In hybrid bonding, a process of applying an impact serving as a trigger for the start of bonding may be executed in step S105. A process of observing the bonding state (bonding deviation amount) between the wafer 6 and the target die 51 after bonding may also be executed in step S105.

Here, the target die 51 is kept held by the bonding head 453 from the start of holding by the bonding head 453 in step S203 to the end of bonding between the wafer 6 and the target die 51 in step S105. That is, holding of the target die 51 by the bonding head 453 is not canceled. After bonding between the wafer 6 and the target die 51 ends in step S105, the controller CNT cancels holding of the target die 51 by the bonding head 453 and increases the interval between the wafer chuck 443 and the bonding head 453. Note that it may be understood that the bonding process includes the alignment between the wafer 6 and the target die 51 in step S104 described above.

Note that steps S106 and S107 are the same as described in the first embodiment, and a detailed description thereof will be omitted here. Note that if there are provided a plurality of bonding stages 45 on which the bonding head 453 is mounted, bonding processes of the target dies 51 to two or more regions on the wafer 6 can be performed parallelly.

### [Offset Amount Decision Method]

The decision method (management method) of the offset amount that can be used in step S104 described above will be described below. As described above, the offset amount can be reflected when performing alignment between the target die 51 and the target region of the wafer 6 based on the position of the target die 51 measured by the die observation camera 441 and the position of the target region of the wafer 6 measured by the wafer observation camera 451. The offset amount decision method according to this embodiment can be performed in accordance with the flowchart of FIG. 5. Matters different from the first embodiment will be described below, and a description of the same matters as in the first embodiment will be omitted.

In step S301, the controller CNT loads the wafer 6 serving as a first object onto the wafer chuck 443 of the bonding apparatus 100C using the wafer conveyance mechanism (not shown). On the wafer 6, a mark used for wafer alignment and a mark used to measure the bonding deviation amount are formed. The wafer 6 preferably undergoes a process such as temporary adhesive application for reducing the position deviation of the test die with respect to the wafer 6 (target region), which occurs at the time of bonding of the test die. After positions of the wafer 6 in the rotational direction and the X and Y directions are measured by a prealignment unit (not shown), the wafer 6 is coarsely positioned based on the measurement result and conveyed onto the wafer chuck 443.

In step S302, the controller CNT performs wafer alignment using the wafer observation camera 451. For example, the controller CNT detects the alignment mark on the wafer 6 using the wafer observation camera 451, and measures the mount position and the rotation amount of the wafer 6 on the wafer chuck 443. Step S302 is the same process as step S102 described above, and a detailed description thereof will be omitted here. During execution of step S302, the surface position of the wafer 6 is preferably measured using a height measurement means (not shown) that measures the surface position (height) of the target bonding surface of the wafer 6. This is because the thickness of the wafer 6 varies, and the surface position of the wafer 6 is important to accurately manage (control) the gap between the wafer 6 and the test die in the bonding process.

In step S303, the controller CNT mounts the test die serving as a second object on the bonding head 453. Next, in step S304, the controller CNT performs die alignment using the die observation camera 441. For example, the controller CNT detects the alignment mark on the test die using the die observation camera 441, and measures the position and the rotation amount of the test die held by the bonding head 453. Step S304 is the same process as step S103 described above, and a detailed description thereof will be omitted here. During execution of step S304, the surface position of the test die is preferably measured using a height measurement means (not shown) that measures the surface position (height) of the target bonding surface of the test die. This is because the thickness of the test die varies, and the surface position of the test die is important to accurately manage (control) the gap between the wafer 6 and the test die in the bonding process. Further, the heights of a plurality of points on the target bonding surface of the test die may be measured to adjust the relative postures of the wafer 6 and the test die based on the measurement result in the bonding process. The relative postures can be adjusted by the tilt mechanism mounted on the bonding stage 45 and/or the bonding head 453.

In step S305, the controller CNT drives the bonding stage 45, thereby performing alignment between the wafer 6 and the test die such that the test die is arranged above the target region of the wafer 6. More specifically, the controller CNT performs alignment between the wafer 6 and the test die based on the position and the rotation amount of the wafer 6 measured in step S302 and the position and the rotation amount of the test die measured in step S304. The alignment can be performed such that the pattern (pad) of the target region of the wafer 6 and the pattern (pad) of the test die overlap each other. Step S305 is the same process as step S104 described above, and a detailed description thereof will be omitted here.

In step S306, the controller CNT bonds the test die to the wafer 6 (bonding process). Step S306 is the same process as step S105 described above, and a detailed description thereof will be omitted here. Next, in step S307, the controller CNT measures the bonding deviation amount between the target region of the wafer 6 and the test die using the wafer observation camera 451. For example, the controller CNT drives the bonding stage 45 such that the bonding point of the test die on the wafer 6 is arranged below the wafer observation camera 451. The controller CNT then causes the wafer observation camera 451 to capture an image of the bonding point, and measures the bonding deviation amount (the position deviation amount or the overlay error) between the wafer 6 (target region) and the test die in the X and Y directions and/or the θZ direction based on the obtained image.

In step S308, the controller CNT calculates an offset amount based on the bonding deviation amount measured in step S307. For example, the controller CNT calculates, as the offset amount, the position deviation amount in the X and Y directions and the rotation amount in the θZ direction for reducing the bonding deviation amount measured in step S307. In the above description, the offset amount is calculated for one region of the wafer 6 to which one test die is bonded. However, it is preferable to calculate the offset amount for each of a plurality of regions on the wafer 6 using a plurality of test dies. The plurality of regions on the wafer 6 are preferably set to positions corresponding to a plurality of regions to which a plurality of dies 51 are bonded in the actual process. Also, the representative value of the offset amounts calculated for the plurality of regions on the wafer 6 may commonly be used in the plurality of regions. Examples of the representative value are an average value, a maximum value, and a mode. If the offset amount changes in accordance with the position of the wafer 6, the offset amount may individually be calculated for each of the plurality of regions on the wafer 6.

An example in which alignment between the wafer 6 and the target die 51 is performed in step S104 of FIG. 3 using the offset amount calculated in the above-described way will be described here. Note that signs change depending on the manner the direction of coordinates is defined, but comply with the coordinate system shown in each drawing in the following example.

Let (Wx, Wy) be the position of the target region of the wafer 6 measured in step S102 with respect to a reference point, and Wθ be the rotation amount. Let (Dx, Dy) be the position of the target die 51 with respect to the center of gravity (center) of the image obtained by the die observation camera 441 in step S103, and Dθ be the rotation amount. Let (Px, Py) be the amount of the shift (shift amount) of the wafer 6 and the target die 51 when bonding the wafer 6 and the target die 51, and Pθ be the rotation amount. Also, as the offset amount obtained in step S308, let (X0, Y0) be the position deviation amount in the X and Y directions, and θ0 be the rotation amount in the θZ direction.

If the offset amount is correctly obtained in step S308, Wx=Wy=Wθ=Dx=Dy=Dθ=0. For this reason, when bonding the target die 51 to the wafer 6, alignment between the wafer 6 and the target die 51 is performed in step S104 such that the target die 51 deviates by the offset amount with respect to the target region of the wafer 6. That is, the bonding stage 45 is arranged such that the position deviation amount in the X and Y directions is (X0, Y0), and the rotation amount in the θZ direction is θ0, and the target die 51 is bonded to the wafer 6. This makes it possible to accurately perform the bonding process at a high position accuracy.

If the position of the wafer 6 is deviated in the bonding process, for example, if the position of the wafer 6 is deviated in the positive direction, the bonding stage 45 is moved in the positive direction, thereby correcting the deviation of the wafer 6. More specifically, in the bonding process, the bonding stage 45 is arranged such that the position deviation amount in the X and Y directions is (X0+Wx, Y0+Wy), and the rotation amount in the θZ direction is (θ0+Wθ).

If the position of the target die 51 is deviated in the bonding process, for example, if the position of the target die 51 is deviated in the positive direction, the bonding stage 45 is moved in the negative direction, thereby correcting the deviation of the target die 51. More specifically, in the bonding process, the bonding stage 45 is arranged such that the position deviation amount in the X and Y directions is (X0+Wx−Dx, Y0+Wy−Dy), and the rotation amount in the θZ direction is (θ0+Wθ−Dθ).

If a shift amount is generated in the bonding process, a position shifted by the amount is set to the bonding position. For example, if the shift amount is generated in the positive direction, the bonding stage 45 is moved by the same amount in the reverse direction (that is, in the negative direction), and the bonding process is then performed. More specifically, in the bonding process, the bonding stage 45 is arranged such that the position deviation amount in the X and Y directions is (X0+Wx−Dx−Px, Y0+Wy−Dy−Py), and the rotation amount in the θZ direction is (θ0+Wθ−Dθ−Pθ).

As described above, the bonding apparatus 100C according to this embodiment includes the surface treatment unit 46 that performs surface treatment of the target bonding surface of the die 51 in a state in which the die 51 is held by the bonding head 453. In the bonding apparatus 100C, after the surface treatment is performed by the surface treatment unit 46, the bonding process of aligning the wafer 6 and the die 51 and bonding the die 51 to the wafer 6 is performed without canceling holding of the die 51 by the bonding head 453. This makes it possible to avoid another member from contacting the target bonding surface of the die 51 between the surface treatment and the bonding process, shorten the time from the surface treatment to the bonding process, and improve the bonding strength between the wafer 6 and the die 51.

### Fourth Embodiment

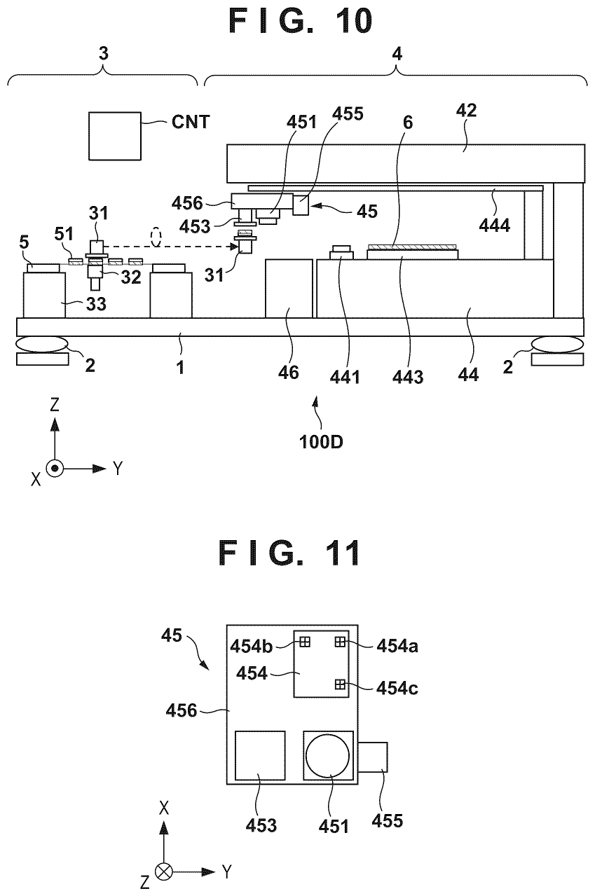

The fourth embodiment according to the present invention will be described. FIG. 10 is a schematic view showing a bonding apparatus 1θ0D according to the fourth embodiment. The bonding apparatus 1θ0D according to this embodiment measures the position of bonding stage using an encoder, as shown in FIG. 10. Note that the fourth embodiment basically inherits the third embodiment and can comply with the third embodiment except matters mentioned below.

The bonding apparatus 1θ0D according to the fourth embodiment is different from the bonding apparatus 100C according to the third embodiment shown in FIG. 8 in that an encoder scale 444 and an encoder head 455 are provided in place of the interferometer 442 and the bar mirror 452. In the bonding apparatus 1θ0D according to the fourth embodiment, the encoder head 455 is provided on a bonding stage 45, and the encoder scale 444 is mounted on a lower base 44. In the encoder scale 444, a two-dimensional scale is formed on a plane such that two-dimensional positioning can be performed. The position of the bonding stage 45 can two-dimensionally be measured by detecting the scale by the encoder head 455. It is preferable that the encoder scale 444 has a low thermal expansion coefficient, and the scale is formed (drawn) at a high position accuracy. As an example of the encoder scale 444, the scale is drawn on a quartz substrate using the drawing method of a semiconductor lithography process. Here, the bonding stage 45 may be constituted by a coarse motion stage that can be driven within a large range, and a fine motion stage that can accurately be driven within a small range on the coarse motion stage. In this case, to perform accurate positioning, the encoder head 455 is preferably fixed to the fine motion stage. The positioning means according to this embodiment includes accurate position measurement by the encoder and feedback control based on the result. Note that a unit formed by the encoder scale 444 and the encoder head 455 will sometimes be referred to as an “encoder” hereinafter.

A method of guaranteeing the origin position, magnification, the X-axis and Y-axis directions (rotation), and the orthogonality of the stage using a reference plate 454 will be described next with reference to FIG. 11. FIG. 11 is a view showing the bonding stage 45 from the −Z direction. While controlling a die observation camera 441 to capture (observe) an image of a mark 454a, a controller CNT obtains the measured value of the encoder when the mark 454a is arranged at the center of the image obtained by the die observation camera 441, and sets the measured value as the origin of the bonding stage 45. Then, while controlling the die observation camera 441 to capture (observe) an image of a mark 454b, the controller CNT obtains the measured value of the encoder when the mark 454b is arranged at the center of the image obtained by the die observation camera 441. From the obtained measured value, the controller CNT decides the Y-axis direction and Y magnification of the bonding stage 45. Next, while controlling the die observation camera 441 to capture (observe) an image of a mark 454c, the controller CNT obtains the measured value of the encoder when the mark 454c is arranged at the center of the image obtained by the die observation camera 441. From the obtained measured value, the controller CNT decides the X-axis direction and × magnification of the bonding stage 45. That is, a direction from the mark 454b toward the mark 454a on the reference plate 454 is defined as the Y-axis of the bonding apparatus 1θ0D, a direction from the mark 454c toward the mark 454a is defined as the X-axis of the bonding apparatus 1θ0D, and the directions and orthogonality of the axes are calibrated. Also, the interval between the mark 454b and the mark 454a is defined as the scale reference of the bonding apparatus 1θ0D in the Y direction, the interval between the mark 454c and the mark 454a is defined as the scale reference of the bonding apparatus 1θ0D in the X direction, and calibration is performed. Since the scale of the encoder thermally expands due to variations of the temperature, and the measured values are different from the actual values (distances), it is preferable that calibration is performed at an arbitrary timing to guarantee the origin position, magnification, rotation, and orthogonality of the bonding stage 45.

Here, the encoder may include a linear encoder for each driving stage. In this case, since variation factors increase between the bonding stage 45 and the measurement point of the encoder, a contrivance of, for example, raising the frequency of calibration or using another measurement method is necessary. If a plurality of encoder heads 455 are arranged and selectively used in accordance with, for example, the bonding position, the footprint of the bonding apparatus 1θ0D can be made small. Alternatively, if a plurality of encoder heads 455 are arranged at positions symmetrically sandwiching the bonding position, and measured values from the plurality of encoder heads 455 are used, the position measurement accuracy of the bonding stage 45 can be improved. In the above description, an example in which calibration is performed by capturing (observing) an image of the reference plate 454 has been described, but the present invention is not limited to this. For example, calibration may be performed by an abutting operation to a reference surface. Alternatively, accurate positioning may be performed by providing a calibration mechanism in the encoder and using a position measurement means for which an absolute value is guaranteed.

The bonding apparatus 1θ0D configured as described above operates like the bonding apparatus 100C according to the third embodiment. That is, in the bonding apparatus 1θ0D as well, a die 51 is bonded to each of a plurality of regions on a wafer 6 in accordance with the flowchart of FIG. 3. In the bonding apparatus 1θ0D, however, for example, in step S104 of FIG. 3, alignment between the wafer 6 and the die 51 can be controlled based on the measured value of the encoder.

### Embodiment of Article Manufacturing Method

A method of manufacturing an article (a semiconductor IC element, a liquid crystal display element, a MEMS, or the like) using the above-described bonding apparatus will be described. The article manufacturing method according to the embodiment of the present invention is suitable for manufacturing an article, for example, a microdevice such as a semiconductor device or an element having a fine structure. The article manufacturing method according to this embodiment includes a step of bonding a second object to each of a plurality of regions of a first object using the above-described bonding apparatus or bonding method, and a step of processing the first object in which the second object is bonded to each of the plurality of regions. The manufacturing method also includes other known processes (for example, probing, dicing, bonding, and packaging). The article manufacturing method according to this embodiment is advantageous in at least one of the performance, quality, productivity, and production cost of the article, as compared to conventional methods.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-195859 filed on Dec. 7, 2022, which is hereby incorporated by reference herein in its entirety.

What is claimed is:

1. A bonding apparatus for performing a bonding process of bonding, to one of a plurality of regions in a first object to be bonded, a second object to be bonded, comprising:
a holder configured to hold the second object;
a surface treatment device configured to perform a surface treatment which includes activating a surface state of a target bonding surface of the second object held by the holder; and
a controller configured to, after the surface treatment is performed for the second object by the surface treatment device, control the bonding process such that the second object is bonded to one of the plurality of regions in a state in which the second object is held by the holder.

2. The apparatus according to claim 1, further comprising a driver configured to drive the holder that holds the second object, thereby moving the second object between a first position at which the surface treatment is performed and a second position at which the bonding process is performed.

3. The apparatus according to claim 2, wherein the driver is configured to translationally drive the holder such that the target bonding surface of the second object faces in the same direction at the first position and the second position.

4. The apparatus according to claim 2, wherein the driver is configured to rotationally drive the holder such that the target bonding surface of the second object faces in different directions at the first position and the second position.

5. The apparatus according to claim 4, wherein the driver is configured to rotationally drive the holder such that a direction of the target bonding surface of the second object is inverted between the first position and the second position.

6. The apparatus according to claim 1, wherein the controller is configured to control the bonding process after alignment between the first object and the second object held by the holder is performed.

7. The apparatus according to claim 6, further comprising an image capturing device configured to capture an image of the target bonding surface of the second object arranged at a second position at which the bonding process is performed,
wherein the controller is configured to perform alignment between the first object and the second object held by the holder based on the image obtained by the image capturing device.

8. The apparatus according to claim 1, wherein the surface treatment includes washing the target bonding surface of the second object.

9. The apparatus according to claim 1, wherein the surface treatment includes making the target bonding surface of the second object lyophilic.

10. The apparatus according to claim 1, wherein the holder holds a surface of the second object on an opposite side of the target bonding surface.

11. The apparatus according to claim 1, further comprising a pickup unit configured to pick up one second object from a plurality of second objects supported by a support member and transfer the one second object to the holder.

12. A bonding method of bonding, to one of a plurality of regions in a first object to be bonded, a second object to be bonded, comprising:
causing a holder to hold the second object;
performing a surface treatment which includes activating a surface state of a target bonding surface of the second object held by the holder; and
after the performing the surface treatment, bonding the second object to one of the plurality of regions in a state in which the second object to be bonded is held by the holder.

13. An article manufacturing method comprising:
bonding, to one of a plurality of regions in a first object to be bonded, a second object to be bonded, using a bonding method defined in claim 12;
processing the first object in which the second object is bonded to one of the plurality of regions; and
manufacturing an article from the processed first object.
